(19) United States
(12) Patent Application Publication
(10) Pub. No.: US 2026/0090247 A1
(43) Pub. Date: Mar. 26, 2026

(54) DISPLAY PANEL, METHOD FOR MANUFACTURING DISPLAY PANEL, AND ELECTRONIC DEVICE

(71) Applicants: Hefei Visionox Technology Co., Ltd., Hefei (CN); Visionox Technology Inc., Jiangsu (CN)

(72) Inventors: Zhiwei ZHOU, Hefei (CN); Wenyu ZENG, Hefei (CN); Zhenhai YUE, Hefei (CN); Jinfang ZHANG, Hefei (CN); Ying SHEN, Hefei (CN); Lu ZHANG, Hefei (CN)

(73) Assignees: Hefei Visionox Technology Co., Ltd., Hefei (CN); Visionox Technology Inc., Jiangsu (CN)

(21) Appl. No.: 19/403,650

(22) Filed: Nov. 28, 2025

Related U.S. Application Data
(63) Continuation of application No. PCT/CN2025/106797, filed on Jul. 3, 2025.

(30) Foreign Application Priority Data
Jul. 26, 2024 (CN) 202411024616.2
Dec. 10, 2024 (CN) 202411832173.X

(51) Int. Cl. H10K 59/80; H10K 59/12; H10K 59/122

(52) U.S. Cl. CPC H10K 59/873; H10K 59/1201; H10K 59/122

(57) ABSTRACT

A display panel, a method for manufacturing a display panel, and an electronic device. The display panel includes a substrate, an isolation structure, a light-emitting unit, an encapsulation unit, and a protective structure. The isolation structure is located on a side of the substrate and surrounds an isolation opening, and an isolation groove is provided on a surface of the isolation structure away from the substrate. The light-emitting unit is at least partially located in the isolation opening. The encapsulation unit is located on a side of the light-emitting unit away from the substrate. The protective structure is located on a side of the isolation structure away from the substrate, and an orthographic projection of the protective structure on the substrate covers at least part of an orthographic projection of the isolation groove on the substrate.

### CROSS-REFERENCE TO RELATED APPLICATIONS

This application is a continuation of International Application No. PCT/CN2025/106797, filed on Jul. 3, 2025, which claims priority to Chinese Patent Application No. 202411024616.2, filed on Jul. 26, 2024 and Chinese Patent Application No. 202411832173.X, filed on Dec. 10, 2024, all of which are incorporated herein by reference in their entireties.

### TECHNICAL FIELD

The present disclosure relates to the field of display technology, and particularly to a display panel, a method for manufacturing a display panel, and an electronic device.

### BACKGROUND

Planar display apparatus based on organic light emitting diode (OLED) and light emitting diode (LED), etc., are widely used in cell phones, TVs, notebook computers, desktop computers and other consumer electronic products due to their high image quality, power saving, thin body, and wide range of applications, and have become the mainstream of the display panel. During the manufacturing of a conventional display panel, the patterning of light-emitting pixels is usually achieved through the fine metal mask (FMM). FMM technology is mature and has extensive mass production experiences. However, FMM technology has some problems such as limited accuracy, high development cost, and long development cycle. Fine-free metal mask technology eliminates the limitations of conventional OLED processes on display size, resolution and other screen performance, and has the advantages of high performance, global size, and agile delivery. Patents application CN118251982A, CN115666161A, CN116648095A, CN117062489A, CN118678742A, CN118785761A, CN115224220A, CN118678729A, CN118660529A, and CN118660589A describe the related contents of fine-free metal mask technology for reference.

However, some problems still need to be urgently solved for the display panel.

### SUMMARY

Some embodiments of the present disclosure provide a display panel. The display panel includes a substrate, an isolation structure, at least one light-emitting unit, at least one encapsulation unit, and at least one protective structure. The isolation structure is located on a side of the substrate and surrounds an isolation opening. At least one isolation groove is provided on a surface of the isolation structure away from the substrate. The at least one light-emitting unit is at least partially located in the isolation opening. The at least one encapsulation unit is located on a side of the at least one light-emitting unit away from the substrate. The at least one protective structure is located on the side of the isolation structure away from the substrate, and an orthographic projection of the at least one protective structure on the substrate covers at least part of an orthographic projection of the at least one isolation groove on the substrate.

In some possible embodiments, the present disclosure provides a display panel. The display panel includes a substrate, an isolation structure, at least one light-emitting unit, at least one encapsulation unit, and a protective portion. The isolation structure is located on a side of the substrate, the isolation structure surrounds an isolation opening, and at least one isolation groove is provided on a surface of the isolation structure away from the substrate. The at least one light-emitting unit is at least partially located in the isolation opening, the at least one encapsulation unit is located on a side of the at least one light-emitting unit away from the substrate, and a protective portion located on the side of the isolation structure away from the substrate and connected to the at least one encapsulation unit. An orthographic projection of the protective portion on the substrate covers at least part of an orthographic projection of the at least one isolation groove on the substrate.

In some possible embodiments, the present disclosure provides a method for manufacturing a display panel, including:
providing a substrate;
forming an isolation structure on a side of the substrate, at least one isolation groove being formed on a surface of the isolation structure away from the substrate, and at least one isolation opening being provided in the isolation structure; and
forming at least one light-emitting unit at least partially located in the at least one isolation opening, at least one encapsulation unit located on a side of the at least one light-emitting unit away from the substrate, and at least one protective structure located on the side of the isolation structure away from the substrate, such that an orthographic projection of the at least one protective structure on the substrate covers at least part of an orthographic projection of the at least one isolation groove on the substrate.

In some possible embodiments, the present disclosure provides an electronic device. The electronic device includes the display panel provided in the present disclosure, or includes the display panel manufactured by the method for manufacturing the display panel provided in the present disclosure.

### BRIEF DESCRIPTION OF THE DRAWINGS

In order to illustrate technical solutions of embodiments of the present disclosure more clearly, drawings used to describe the embodiments of the present disclosure are introduced briefly below. It should be understood that the drawings described below only show some embodiments of the present disclosure, and thus should not be regarded as a limitation of the scope. For those skilled in the art, other related drawings can be obtained from these drawings without creative efforts.

FIG. 1 is a schematic cross-sectional view of a display panel in which a protective structure is provided on an isolation groove according to some embodiments of the present disclosure;

FIG. 2 is a schematic cross-sectional view of a display panel in which a protective structure includes a protective layer according to some embodiments of the present disclosure;

FIG. 3 is a cross-sectional view of a display panel in which the protective structure includes a first auxiliary protective layer and a second auxiliary protective layer according to some embodiments of the present disclosure;

FIG. 4 is a first schematic top view showing a relationship between an encapsulation unit and an isolation groove according to some embodiments of the present disclosure;

FIG. 5 is a schematic cross-sectional view along M-M in FIG. 4 according to some embodiments of the present disclosure;

FIG. 6 is a second schematic top view showing a relationship between an encapsulation unit and an isolation groove according to some embodiments of the present disclosure.

FIG. 7 is a schematic cross-sectional view along A-A in FIG. 6 according to some embodiments of the present disclosure;

FIG. 8 is a third schematic top view showing a relationship between an encapsulation unit and an isolation groove according to some embodiments of the present disclosure;

FIG. 9 is a schematic cross-sectional view along B-B in FIG. 8 according to some embodiments of the present disclosure;

FIG. 10 is a fourth schematic top view showing a relationship between an encapsulation unit and an isolation groove according to some embodiments of the present disclosure;

FIG. 11 is a schematic cross-sectional view along C-C in FIG. 10 according to some embodiments of the present disclosure;

FIG. 12 is a fifth schematic top view showing a relationship between an encapsulation unit and an isolation groove according to some embodiments of the present disclosure;

FIG. 13 is a schematic cross-sectional view along D-D in FIG. 12 according to some embodiments of the present disclosure;

FIG. 14 is a schematic cross-sectional view along E-E in FIG. 12 according to some embodiments of the present disclosure;

FIG. 15 is a sixth schematic top view showing a relationship between an encapsulation unit and an isolation groove according to some embodiments of the present disclosure;

FIG. 16 is a first schematic cross-sectional view along F-F in FIG. 15 according to some embodiments of the present disclosure;

FIG. 17 is a first schematic cross-sectional view along G-G in FIG. 15 according to some embodiments of the present disclosure;

FIG. 18 is a second schematic cross-sectional view along F-F in FIG. 15 according to some embodiments of the present disclosure;

FIG. 19 is a second schematic cross-sectional view along G-G in FIG. 15 according to some embodiments of the present disclosure;

FIG. 20 is a third schematic cross-sectional view along G-G in FIG. 15 according to some embodiments of the present disclosure;

FIG. 21 is a schematic cross-sectional view showing a fifth groove being disposed on a side of the encapsulation unit away from the substrate according to some embodiments of the present disclosure;

FIG. 22 is a schematic cross-sectional view showing an isolation structure including a two-layer structure according to some embodiments of the present disclosure;

FIG. 23 is a schematic cross-sectional view showing an isolation structure including a three-layer structure according to some embodiments of the present disclosure;

FIG. 24 is a schematic cross-sectional view of a display panel including a second encapsulation layer and a third encapsulation layer according to some embodiments of the present disclosure;

FIG. 25 is a schematic flowchart of a method for manufacturing a display panel according to embodiments of the present disclosure;

FIG. 26 is a schematic cross-sectional view in which a circuit structure layer, an insulation layer, and a first electrode layer are sequentially formed on a side of the substrate, according to some embodiments of the present disclosure;

FIG. 27 is a schematic cross-sectional view in which a pixel defining material layer is formed on a side of a first electrode layer away from the substrate according to some embodiments of the present disclosure;

FIG. 28 is a schematic cross-sectional view in which an isolation material layer is formed on a side of a pixel defining material layer away from the substrate, according to some embodiments of the present disclosure;

FIG. 29 is a schematic cross-sectional view in which the insulation material layer and the pixel defining material layer are sequentially patterned, according to some embodiments of the present disclosure;

FIG. 30 is a schematic cross-sectional view in which a first light-emitting material layer is formed in a first isolation opening, according to some embodiments of the present disclosure;

FIG. 31 is a schematic cross-sectional view in which a first encapsulation unit material layer is formed on a side of the first light-emitting material layer away from the substrate, according to some embodiments of the present disclosure;

FIG. 32 is a cross-sectional view in which a first etching protective layer is formed on a side, away from the substrate, of a first encapsulation unit material layer of a first light-emitting unit, according to some embodiments of the present disclosure;

FIG. 33 is a cross-sectional view in which the first encapsulation unit material layer and the first light-emitting material layer that are not covered by the first etching protective layer is removed, according to some embodiments of the present disclosure;

FIG. 34 is a cross-sectional view in which a second light-emitting material layer is formed in a second isolation opening, according to some embodiments of the present disclosure;

FIG. 35 is a cross-sectional view in which a first encapsulation unit material layer is formed on a side of a second light-emitting material layer away from the substrate, according to some embodiments of the present disclosure;

FIG. 36 is a schematic cross-sectional view in which a second etching protective layer is formed on a side, away from the substrate, of a first encapsulation unit material layer of a second light-emitting unit, according to some embodiments of the present disclosure;

FIG. 37 is a schematic cross-sectional view in which the first encapsulation unit material layer and the second light-emitting material layer that are not covered by the second etching protective layer are removed, according to some embodiments of the present disclosure.

FIG. 38 is a schematic cross-sectional view in which a third light-emitting material layer is formed in a third isolation opening, according to some embodiments of the present disclosure;

FIG. 39 is a schematic cross-sectional view in which a first encapsulation unit material layer is formed on a side of a third light-emitting material layer away from the substrate, according to some embodiments of the present disclosure;

FIG. 40 is a schematic cross-sectional view in which a third etching protective layer is formed on a side, away from the substrate, of a first encapsulation unit material layer of the third light-emitting unit, according to some embodiments of the present disclosure;

FIG. 41 is a schematic cross-sectional view in which a first light-emitting material layer, a first encapsulation unit material layer, and a fourth etching protective layer are sequentially formed in a first isolation opening in a direction away from a substrate, according to some embodiments of the present disclosure;

FIG. 42 is a cross-sectional view in which the first encapsulation unit material layer and the first light-emitting material layer that are not covered by the fourth etching protective layer are removed and the fourth etching protective layer is removed, according to some embodiments of the present disclosure;

FIG. 43 is a first cross-sectional view in which a second light-emitting unit and an encapsulation unit located on a side of the second light-emitting unit away from the substrate are formed in a second isolation opening, according to some embodiments of the present disclosure;

FIG. 44 is a schematic cross-sectional view in which a first light-emitting unit and an encapsulation unit located on a side of the first light-emitting unit away from the substrate are formed in a first isolation opening, according to some embodiments of the present disclosure;

FIG. 45 is a second cross-sectional view in which a second light-emitting unit and an encapsulation unit located on a side of the second light-emitting unit away from the substrate are formed in a second isolation opening, according to some embodiments of the present disclosure;

FIG. 46 is a schematic cross-sectional view in which a first light-emitting unit, and an encapsulation unit, a first cover portion, and a second cover portion that are located on a side of the first light-emitting unit away from the substrate are formed in a first isolation opening, according to some embodiments of the present disclosure;

FIG. 47 is a third schematic cross-sectional view in which a second light-emitting unit and an encapsulation unit located on a side of the second light-emitting unit away from the substrate are formed in a second isolation opening, according to some embodiments of the present disclosure;

FIG. 48 is a schematic cross-sectional view of a display panel in which a third light-emitting unit and an encapsulation unit located on a side of the third light-emitting unit away from the substrate are formed in a third isolation opening, according to some embodiments of the present disclosure; and

FIG. 49 is a schematic cross-sectional view of a display panel without a protective structure according to some embodiments of the present disclosure.

### DETAILED DESCRIPTION

It should be noted that similar reference numbers and letters indicate similar items in the following drawings. Therefore, once a certain item is defined in one drawing, it does not need to be defined and explained in the subsequent drawings.

In the description of the present disclosure, it should be noted that terms “center”, “upper”, “lower”, “vertical”, “horizontal”, “inner”, “outer”, and the like indicate orientations or positional relationships based on the orientations or the positional relationships shown in the drawings or based on the orientations or the positional relationships in which the inventive product is placed commonly when in use, which are merely to facilitate and simplify the description of the present disclosure, rather than to indicate or imply that the referenced apparatuses or elements must have a particular orientation, or be constructed and operated in a particular orientation. Accordingly, no limitations are intended to the present disclosure. In addition, the terms “first”, “second”, “third” and the like are only used for distinguishing descriptions, and cannot be understood as indicating or implying relative importance.

It is to be illustrated that different features in the embodiments of the present disclosure can be combined with each other when they are not in conflict with each other.

Increasing the density of light-emitting units (i.e., pixel density) in the display panel is an important way to improve the display effect. However, the display panel manufactured by fine metal mask (FMM) technology cannot further increase the density of light-emitting units due to technical limitations. According long-term researches, it is found that to solve the technical problem that the density of the light-emitting units cannot be further improved, some display panels are provided with an isolation structure, the light-emitting functional layer and the second electrode can be disconnected at the isolation structure when the light-emitting functional layer and the second electrode each are evaporated as a whole layer, and light-emitting units of different colors can be formed in different isolation openings through multiple evaporation and multiple etching processes (i.e., patterning the light-emitting unit).

In the related art, a display panel includes a substrate and an isolation structure located on a side of the substrate, the isolation structure surrounds isolation openings, and grooves are provided on a surface of the isolation structure away from the substrate. During the formation process of the light-emitting unit, the second electrode of the light-emitting unit is relatively thin at the groove. During the patterning process of the light-emitting unit, the second electrode at the groove cannot effectively block etching of the isolation structure. After subsequent etching, the isolation structure can be etched to form a cavity, ultimately damaging the encapsulation layer of the light-emitting unit, causing the encapsulation failure of the light-emitting unit, and thus affecting the display effect of the display panel.

To solve the above technical problems, the following technical solutions are innovatively designed, and the specific embodiments of the present disclosure will be described in detail below with reference to the accompanying drawings. It should be noted that the defects in the solutions in the prior art are the results obtained through practice and careful research. Therefore, the discovery process of the above technical problems and the solutions to the above problems proposed in the embodiments below should be regarded as the contributions provided in the present disclosure during the process, and should not be understood as technical contents known to those skilled in the art.

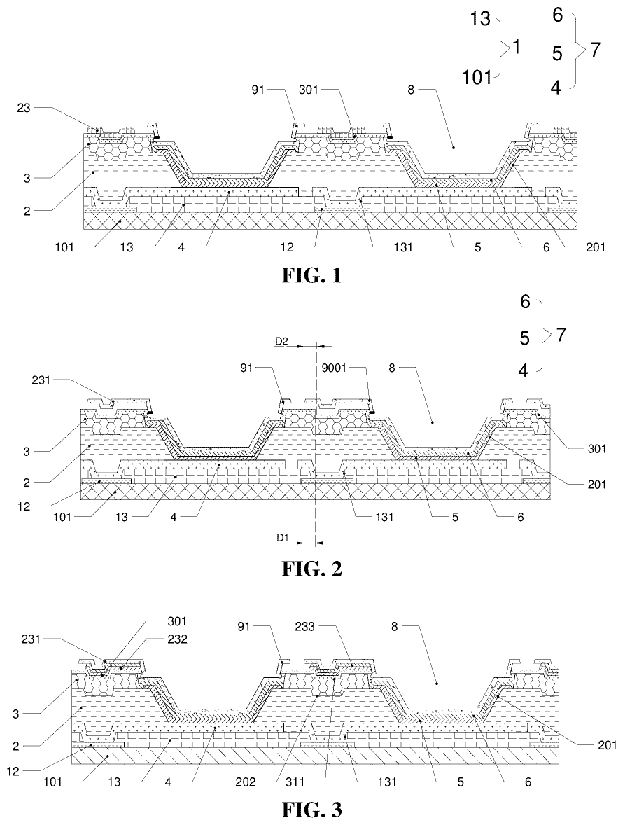

Referring to FIG. 1, some embodiments provide a display panel, which includes a substrate, an isolation structure 3, a light-emitting unit 7, an encapsulation unit 91, and a protective structure 23.

The isolation structure 3 is located on a side of the substrate, the isolation structure 3 surrounds isolation openings 8, and an isolation groove 301 is provided on a surface of the isolation structure 3 away from the substrate.

At least part of the light-emitting unit 7 is located in the isolation opening 8, and the encapsulation unit 91 is located on the side of the light-emitting unit 7 away from the substrate.

The protective structure 23 is located on a side of the isolation structure 3 away from the substrate, and an orthographic projection of the protective structure 23 on the substrate covers at least part of an orthographic projection of the isolation groove 301 on the substrate.

The light-emitting units 7 include a first light-emitting unit, a second light-emitting unit, and a third light-emitting unit. Since the orthographic projection of the protective structure 23 on the substrate covers at least part of the orthographic projection of the isolation groove 301 on the substrate, the protective structure 23 can protect the isolation structure 3 at the isolation groove 301 during the formation process of the second light-emitting unit and the third light-emitting unit, and plays an etch blocking role for the isolation structure 3 at the isolation groove 301, so that the isolation structure 3 at the isolation groove 301 corresponding to the first light-emitting unit is less prone to over-etching, thereby causing it less likely to damage the encapsulation unit 91 corresponding to the first light-emitting unit, and less likely to cause the encapsulation failure of the first light-emitting unit.

Similarly, since the orthographic projection of the protective structure 23 on the substrate covers at least part of the orthographic projection of the isolation groove 301 on the substrate, during the formation process of the third light-emitting unit, the protective structure 23 can protect the isolation structure 3 at the isolation groove 301, so that the isolation structure 3 at the isolation groove 301 corresponding to the second light-emitting unit is less prone to over-etching, thereby causing it less likely to damage the encapsulation unit 91 corresponding to the second light-emitting unit, less likely to cause the encapsulation failure of the second light-emitting unit, and finally, the display effect of the display panel can be improved.

Based on the above design, in the present embodiment, by setting the orthographic projection of the protective structure 23 on the substrate to cover at least part of the orthographic projection of the isolation groove 301 on the substrate, the isolation structure 3 at the isolation groove 301 can protected, so that the etching damage to the isolation structure 3 at the isolation groove 301 can be reduced, causing it less likely to damage the encapsulation unit 91 of the light-emitting unit 7, and thus the encapsulation performance of the display panel can be improved.

In some possible embodiments, referring to FIG. 2, the protective structure 23 includes a protective layer 231 having a same material as the encapsulation unit 7, and the orthographic projection of the isolation groove 301 on the substrate is located in the orthographic projection of the protective layer 231 on the substrate. Therefore, the protective effect of the protective layer 231 on the isolation structure 3 at the isolation groove 301 causes the isolation structure 3 at the isolation groove 301 less prone to over-etching, thereby further causing the light-emitting unit 7 less prone to encapsulation failure.

In some embodiments, the protective layer 231 is connected to the encapsulation unit 91. The protective layer 231 can be regarded as an extension part of the encapsulation unit 91, and thus the stability of the protective layer 231 can be improved.

In some embodiments, still referring to FIG. 2, a minimum distance D1 between an edge of the orthographic projection of the isolation groove 301 on the substrate and an edge of the orthographic projection of the protective layer 231 on the substrate is greater than or equal to 0 μm. For example, the minimum distance D1 can be 0 μm, 0.5 μm, 0.6 μm, 0.7 μm, or the like. In this way, the protective layer 231 can completely cover the corresponding isolation groove 301.

In some embodiments, a minimum distance D2 between an edge of an orthographic projection of a bottom wall of the isolation groove 301 on the substrate and the edge of the orthographic projection of the protective layer 231 on the substrate is greater than or equal to 0.5 μm and smaller than or equal to 8 μm. For example, the minimum distance D2 can be 0.5 μm, 0.6 μm, 0.7 μm, 0.8 μm, 0.9 μm, 1 μm, 2 μm, 5 μm, 7 μm, 7.5 μm, 7.8 μm, 8 μm, or the like. By reasonably setting the minimum distance D2, the protective effect of the protective layer 231 on the isolation structure 3 at the isolation groove 301 can be further improved, making the light-emitting unit 7 less prone to encapsulation failure.

In some possible embodiments, referring to FIG. 3, the protective structure 23 includes a first auxiliary protective layer 232 located between the protective layer 231 and the isolation structure 3, and an orthographic projection of the first auxiliary protective layer 232 on the substrate 1 covers at least part of the orthographic projection of the isolation groove 301 on the substrate 1.

In this way, the protective layer 231 and the first auxiliary protective layer 232 jointly protect the isolation groove 301, so that the protective effect on the isolation structure 3 at the isolation groove 301 can be further improved.

In some embodiments, the first auxiliary protective layer 232 is in contact with a surface of the isolation structure 3 away from the substrate 1.

In some embodiments, the orthographic projection of the first auxiliary protective layer 232 on the substrate 1 completely covers the orthographic projection of the isolation groove 301 on the substrate 1.

In some embodiments, the light-emitting unit 7 includes a first electrode 4, a light-emitting portion 5, and a second electrode 6 that are stacked on a side of the substrate 1, and the first auxiliary protective layer 232 and the light-emitting portion 5 are provided in a same layer.

In some embodiments, a material of the first auxiliary protective layer 232 is the same as a material of the light emitting portion 5.

In this way, the first auxiliary protective layer 232 can be formed simultaneously with the light-emitting portion 5, without a specific process of forming the first auxiliary protective layer 232, thereby reducing the cost of forming the first auxiliary protective layer 232.

In some embodiments, the first auxiliary protective layer 232 is spaced apart from the light emitting portion 5. In this way, the first auxiliary protective layer 232 does not affect the light-emitting unit 5, and thus the light-emitting effect of the light-emitting unit 7 is less likely to be affected.

In some possible embodiments, still referring to FIG. 3, the protective structure 23 includes a second auxiliary protective layer 233 located between the protective layer 231 and the first auxiliary protective layer 232, and an orthographic projection of the second auxiliary protective layer 233 on the substrate 1 covers at least part of the orthographic projection of the isolation groove 301 on the substrate 1.

In this way, the protective layer 231, the first auxiliary protective layer 232, and the second auxiliary protective layer 233 jointly protect the isolation groove 301, so that the protective effect on the isolation structure 3 at the isolation groove 301 can be further improved.

In some embodiments, the second auxiliary protective layer 233 is in contact with a surface of the protective layer 231 close to the substrate 1.

In some embodiments, the orthographic projection of the second auxiliary protective layer 233 on the substrate 1 completely covers the orthographic projection of the isolation groove 301 on the substrate 1.

In some embodiments, the second auxiliary protective layer 233 and the second electrode 6 are provided in a same layer.

In some embodiments, a material of the second auxiliary protective layer 233 is the same as a material of the second electrode 6.

In this way, the second auxiliary protective layer 233 can be formed simultaneously with the second electrode 6, without a specific process of forming the second auxiliary protective layer 233, thereby reducing the cost of forming the second auxiliary protective layer 233.

In some embodiments, the second auxiliary protective layer 233 is spaced apart from the second electrode 6. In this way, the second auxiliary protective layer 233 does not affect the second electrode 6, and thus the light-emitting effect of the light emitting unit 7 is less likely to be reduced.

In some possible embodiments, still referring to FIG. 3, the display panel includes a pixel defining layer 2 located on a side of the first electrode 4 away from the substrate, and the isolation structure 3 is located on a side of the pixel defining layer 2 away from the substrate; the pixel defining layer 2 includes a pixel opening 201 exposing at least part of the first electrode 4, and the orthographic projection of the isolation structure 3 on the substrate is located between orthographic projections of two adjacent pixel openings 201 on the substrate; the orthographic projection of the pixel opening 201 on the substrate 1 is located in the orthographic projection of the isolation opening 8 on the substrate 1.

The isolation structure 3 is provided, so that layers of the light-emitting units 7 of different colors in different isolation openings 8 are formed in the display panel without a fine metal mask. When the light-emitting functional layer is formed, the light-emitting functional layer is separated by the isolation structure 3 to form multiple light-emitting portions 5 that are spaced apart from each other; when the second electrode layer is formed, the second electrode layer is separated by the isolation structure 3 to form multiple second electrodes 6 that are spaced apart from each other; the isolation structure 3 includes a conductive material, the second electrode 6 is electrically connected to the isolation structure 3, and one first electrode 4, one light-emitting portion 5, and one second electrode 6 form one light-emitting unit 7. The first electrode 4 can be an anode, and the second electrode 6 can be a cathode.

In this way, different light-emitting units 7 can be independent of each other, thereby reducing crosstalk between adjacent light-emitting units 7 and thus improving the display effect of the display panel. Meanwhile, due to providing the isolation structure 3, the light-emitting functional layer and the second electrode layer in the light-emitting unit 7 of each color in the display panel each can be manufactured in a form of a full surface first and then is patterned, so that the fine metal mask can be eliminated, and the preparation cost of the display panel can be saved.

In some embodiments, still referring to FIG. 3, the substrate 1 includes a base substrate 101, a circuit structure layer, and an insulation layer 13 located on a side of the base substrate 101, the circuit structure layer includes a circuit structure 121, the insulation layer 13 is provided with a via 131 penetrating the insulation layer 13, an orthographic projection of the isolation groove 301 on the base substrate 101 is located in an orthographic projection of the via 131 on the substrate 101, a second groove 202 is provided on a surface of the pixel definition layer 2 away from the base substrate 101, an orthographic projection of the second groove 202 on the base substrate 101 is located in the orthographic projection of the via 131 on the base substrate 101, the orthographic projection of the isolation groove 301 on the base substrate 101 is located in the orthographic projection of the second groove 202 on the base substrate 101, and the first electrode 4 is electrically connected to the circuit structure 121 through the via 131.

In this embodiment, the circuit structure 121 can be a fourth conductive layer in the display panel. Since the via 131 connecting the first electrode 4 and the circuit structure 121 is provided in the insulation layer 13, the second groove 202 is naturally formed on the pixel definition layer 2 at the via 131, and the isolation groove 301 is naturally formed at the second groove 202 on a surface of the isolation structure 3 away from the base substrate 101, the orthographic projection of the second groove 202 on the base substrate 101 is located in the orthographic projection of the via 131 on the base substrate 101, and the orthographic projection of the isolation groove 301 on the base substrate 101 is located in the orthographic projection of the second groove 202 on the base substrate 101.

Referring to FIGS. 4 and 5, the light-emitting units include a first light-emitting unit, a second light-emitting unit, and a third light-emitting unit that have different light-emitting colors; the encapsulation units 91 include a first encapsulation unit 911 located on a side of the first light-emitting unit away from the substrate 1, a second encapsulation unit 912 located on a side of the second light-emitting unit away from the substrate 1, and a third encapsulation unit 913 located on a side of the third light-emitting unit away from the substrate 1; the isolation opening 8 includes a first isolation opening 8181, a second isolation opening 8282, and a third isolation opening 8383, the first light-emitting unit is located in the first isolation opening 8181, the second light-emitting unit is located in the second isolation opening 82, and the third light-emitting unit is located in the third isolation opening 83.

In some possible embodiments, referring to FIGS. 4 and 5, the protective layer 231 includes at least one type of protective layer 231 corresponding to one of the first encapsulation unit 911, the second encapsulation unit 912, and the third encapsulation unit 913. One type of protective layer 231 of the at least one type of protective layer 231 covers the isolation groove 301 corresponding to one type, two types, or three types of light-emitting units 7. The isolation groove 301 corresponding to the via 131 of the first electrode 4 of the first light-emitting unit is one type of isolation groove 301, the isolation groove 301 corresponding to the via 131 of the first electrode 4 of the second light-emitting unit is another type of isolation groove 301, and the isolation groove 301 corresponding to the via 131 of the first electrode 4 of the third light-emitting unit is yet another type of isolation groove 301. There are three types of light-emitting units and three types of isolation grooves 301 in total. That is, there can be only one type of protective layer in the product, and the only one type of protective layer protects the isolation groove corresponding to one type, two types, or three types of light-emitting units; or there can be two or three types of protective layers on the product, and these two or three types of protective layers collectively protect the isolation groove corresponding to one type, two types, or three types of light-emitting units.

In some embodiments, the protective layer 231 includes at least two types of protective layers 231 corresponding to one of the first encapsulation unit 911, the second encapsulation unit 912, and the third encapsulation unit 913, and at least two of the at least two types of protective layers 231 partially overlap.

During the preparation process of the display panel, the light-emitting portion and the second electrode of the second light-emitting unit between the second encapsulation unit and the first encapsulation unit are removed; therefore, a height H1 of a first gap is within a range of 80% to 120% of a sum of a thickness of the light-emitting portion of the second light-emitting unit and a thickness of the second electrode of the second light-emitting unit. For example, the height H1 is 80%, 90%, 100%, 110%, 120%, or the like of the sum of the thicknesses of the light-emitting portion and the second electrode of the second light-emitting unit.

In some embodiments, along a thickness direction Z of the substrate, a second gap is provided between overlapping portions of the second encapsulation unit and the third encapsulation unit.

In some embodiments, along the thickness direction Z of the substrate, a height H2 of the second gap is within a range of 80% to 120% of a sum of a thickness of the light-emitting portion of the third light-emitting unit and a thickness of the second electrode of the third light-emitting unit. For example, the height H2 is 80%, 90%, 100%, 110%, 120%, or the like of the sum of the thicknesses of the light-emitting portion and the second electrode of the third light-emitting unit.

During the preparation process of the display panel, the light-emitting portion and the second electrode of the third light-emitting unit between the second encapsulation unit and the third encapsulation unit are removed; therefore, the height H2 of the second gap is within a range of 80% to 120% of the sum of the thicknesses of the light-emitting portion and the second electrode of the third light-emitting unit.

The isolation groove 301 includes a first isolation groove 3011 corresponding to the first light-emitting unit, a second isolation groove 3012 corresponding to the second light-emitting unit, and a third isolation groove 3013 corresponding to the third light-emitting unit. Specifically, the isolation groove 301 corresponding to the via 131 of the first electrode 4 of the first light-emitting unit is the first isolation groove 3011 corresponding to the first light-emitting unit; the isolation groove 301 corresponding to the via 131 of the first electrode 4 of the second light-emitting unit is the second isolation groove 3012 corresponding to the second light-emitting unit; the isolation groove 301 corresponding to the via 131 of the first electrode 4 of the third light-emitting unit is the third isolation groove 3013 corresponding to the third light-emitting unit. Several embodiments in which the protective layer 231 covers the isolation groove 301 are described below.

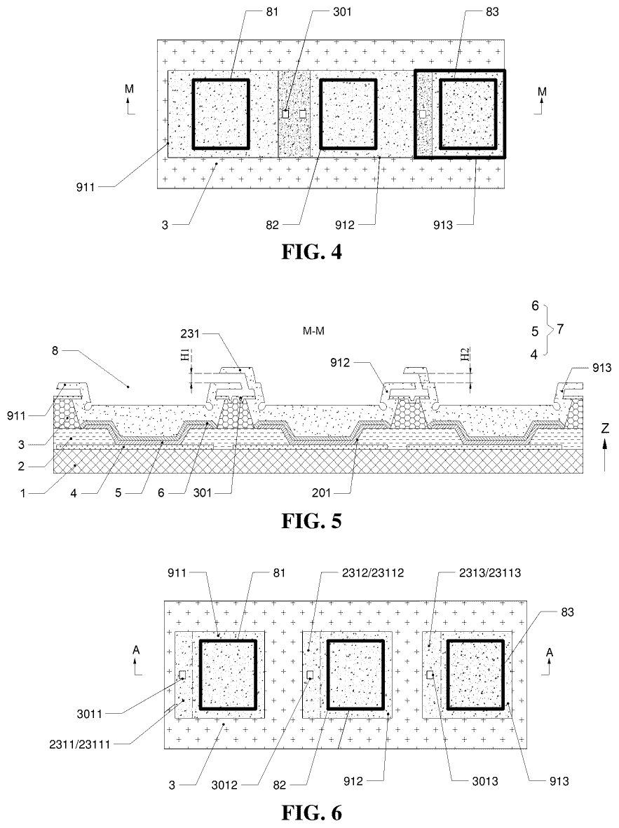

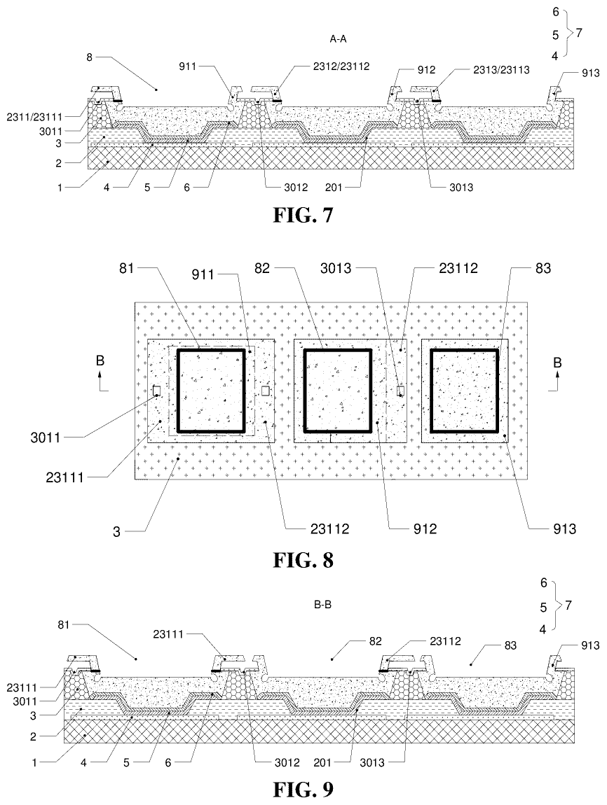

In a first embodiment, referring to FIGS. 6 and 7, the protective layer 231 includes a first protective layer 2311 corresponding to the first encapsulation unit 911, a second protective layer 2312 corresponding to the second encapsulation unit 912, and a third protective layer 2313 corresponding to the third encapsulation unit 913. The first protective layer 2311 covers the first isolation groove 3011, the second protective layer 2312 covers the second isolation groove 3012, and the third protective layer 2313 covers the third isolation groove 3013. The first protective layer 2311 is connected to the first encapsulation unit 911, and therefore the first protective layer 2311 corresponds to the first encapsulation unit 911; the second protective layer 2312 is connected to the second encapsulation unit 912, and therefore the second protective layer 2312 corresponds to the second encapsulation unit 912; the third protective layer 2313 is connected to the third encapsulation unit 913, and therefore the third protective layer 2313 corresponds to the third encapsulation unit 913.

In a second embodiment, still referring to FIGS. 6 and 7, the first protective layer 2311 includes a first protective portion 23111 corresponding to the first encapsulation unit 911, a second protective portion 23112 corresponding to the second encapsulation unit 912, and a third protective portion 23113 corresponding to the third encapsulation unit 913. The first protective portion 23111 covers the first isolation groove 3011, the second protective portion 23112 covers the second isolation groove 3012, and the third protective portion 23113 covers the third isolation groove 3013.

In a third embodiment, referring to FIGS. 8 and 9, the first protective portion 23111 covers the first isolation groove 3011 and the second isolation groove 3012, and the second protective portion 23112 covers the third isolation groove 3013.

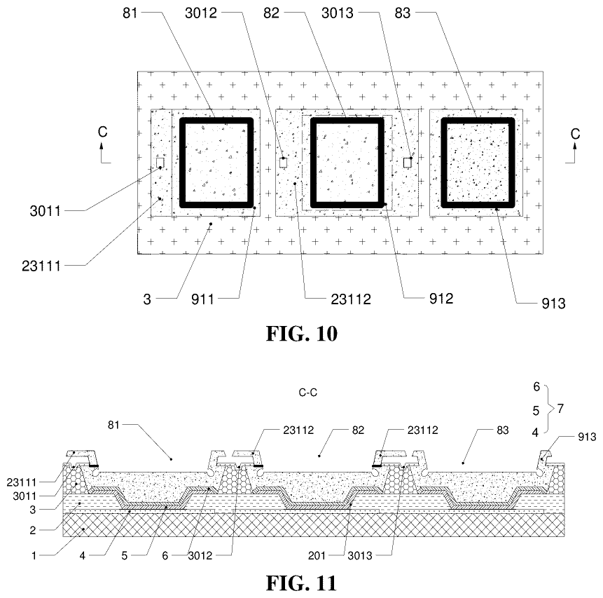

In a fourth embodiment, referring to FIGS. 10 to 11, the first protective portion 23111 covers the first isolation groove 3011, and the second protective portion 23112 covers the second isolation groove 3012 and the third isolation groove 3013.

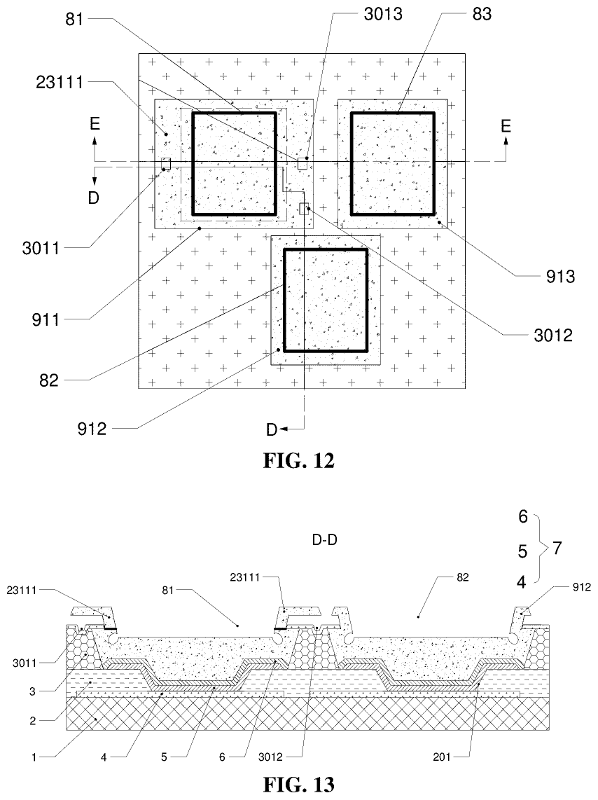

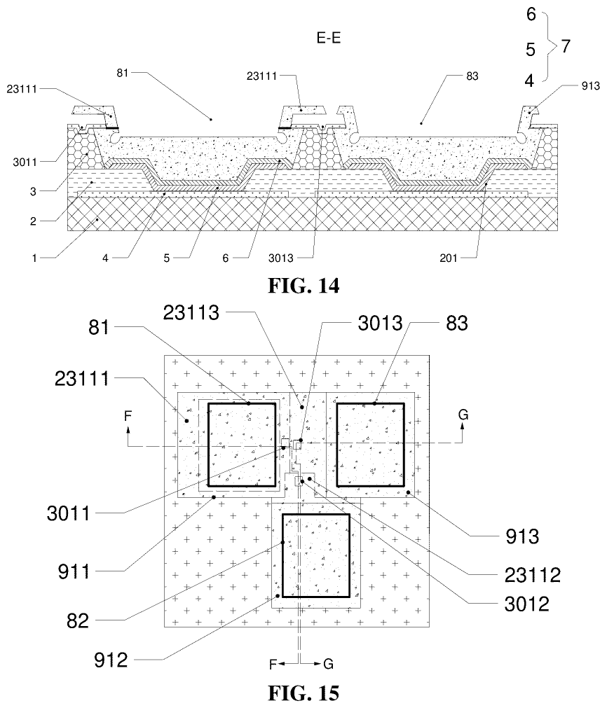

In a fifth embodiment, referring to FIGS. 12 to 14, the first protective portion 23111 covers the first isolation groove 3011, the second isolation groove 3012, and the third isolation groove 3013.

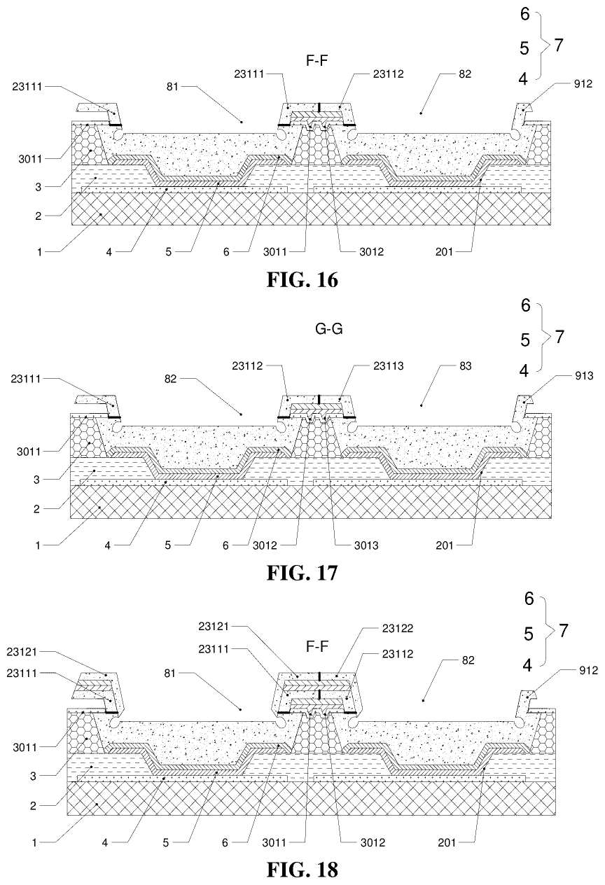

In a sixth embodiment, referring to FIGS. 15 to 17, the second isolation groove 3012 is located at a side of the second light-emitting unit close to the first light-emitting unit, and the first protective portion 23111 and the second protective portion 23112 are formed into one piece.

Optionally, the second isolation groove 3012 is located at the side of the second light-emitting unit close to the first light-emitting unit, the third isolation groove 3013 is located at the side of the third light-emitting unit close to the first light-emitting unit, and the first protective portion 23111, the second protective portion 23112, and the third protective portion 23113 are formed into one piece. In this way, the connections between the first protective portion 23111, the second protective portion 23112, and the third protective portion 23113 are more stable, and the first isolation groove 3011, the second isolation groove 3012, and the third isolation groove 3013 can be better protected.

In some embodiments, the first isolation groove 3011 and the second isolation groove 3012 are located between the first light-emitting unit and the second light-emitting unit, and the first protective portion 23111 and the second protective portion 23112 are formed into one piece.

Optionally, the second isolation groove 3012 and the third isolation groove 3013 are located between the second light-emitting unit and the third light-emitting unit, and the second protective portion 23112 and the third protective portion 23113 are formed into one piece.

By concentrating the first isolation groove 3011, the second isolation groove 3012, and the third isolation groove 3013 together, the protective effect of the first protective portion 23111 on the first isolation groove 3011, the protective effect of the second protective portion 23112 on the second isolation groove 3012, and the protective effect of the third protective portion 23113 on the third isolation groove 3013 can be improved.

In some embodiments, the first protective layer 2311 and the first encapsulation unit 911 are provided in a same layer and made of a same material.

In this embodiment, the first protective portion 23111, the second protective portion 23112, and the third protective portion 23113 can be formed simultaneously with the first encapsulation unit 911, thereby eliminating the need for the specific processes of forming the first protective portion 23111, the second protective portion 23112, and the third protective portion 23113, and thus reducing the cost of forming the first protective portion 23111, the second protective portion 23112, and the third protective portion 23113.

In a seventh embodiment, referring to FIGS. 15, 18, and 19, based on the sixth embodiment, the second protective layer 2312 includes a fourth protective portion 23121 corresponding to the first encapsulation unit 911, a fifth protective portion 23122 corresponding to the second encapsulation unit 912, and a sixth protective portion 23123 corresponding to the third encapsulation unit 913; the fourth protective portion 23121 covers the first isolation groove 3011, the fifth protective portion 23122 covers the second isolation groove 3012, and the sixth protective portion 23123 covers the third isolation groove 3013; the fourth protective portion 23121 is located on a side of the first protective portion 23111 away from the substrate 1, the fifth protective portion 23122 is located on a side of the second protective portion 23112 away from the substrate 1, and the sixth protective portion 23123 is located on a side of the third protective portion 23113 away from the substrate 1.

In this way, the fourth protective portion 23121 and the first protective portion 23111 jointly protect the first isolation groove 3011, the fifth protective portion 23122 and the second protective portion 23112 jointly protect the second isolation groove 3012, and the sixth protective portion 23123 and the third protective portion 23113 jointly protect the third isolation groove 3013, thereby further improving the protective effect on the first isolation groove 3011, the second isolation groove 3012, and the third isolation groove 3013.

In some embodiments, the second isolation groove 3012 is located at the side of the second light-emitting unit close to the first light-emitting unit, and the fourth protection portion 23121 and the fifth protection portion 23122 are formed into one piece.

Optionally, the second isolation groove 3012 is located at the side of the second light-emitting unit close to the first light-emitting unit, the third isolation groove 3013 is located at the side of the second light-emitting unit close to the first light-emitting unit, and the fourth protection portion 23121, the fifth protection portion 23122, and the sixth protection portion 23123 are formed into one piece.

In this way, the stability of the fourth protective portion 23121, the fifth protective portion 23122, and the sixth protective portion 23123 can be improved, and the protective effect on the first isolation groove 3011, the second isolation groove 3012, and the third isolation groove 3013 can be further improved.

In some embodiments, the first isolation groove 3011 and the second isolation groove 3012 are located between the first light-emitting unit and the second light-emitting unit, and the fourth protective portion 23121 and the fifth protective portion 23122 are formed into one piece.

In this way, concentrating the first isolation groove 3011 and the second isolation groove 3012 together can improve the protective effect on the first isolation groove 3011 and the second isolation groove 3012.

Optionally, the second isolation groove 3012 and the third isolation groove 3013 are located between the second light-emitting unit and the third light-emitting unit, and the fifth protection portion 23122 and the sixth protection portion 23123 are formed into one piece.

In this way, concentrating the second isolation groove 3012 and the third isolation groove 3013 together can improve the protective effect on the second isolation groove 3012 and the third isolation groove 3013.

In some embodiments, the second protective layer 2312 and the second encapsulation unit 912 are provided in a same layer and made of a same material.

In this embodiment, the second protective layer 2312 can be formed simultaneously with the second encapsulation unit 912, thereby eliminating the need for a specific process of forming the second protective layer 2312.

In an eighth embodiment, referring to FIGS. 15, 17, and 20, based on the sixth implementation mode, the second protective layer 2312 includes a fourth protective portion 23121 corresponding to the first encapsulation unit 911 and a fifth protective portion 23122 corresponding to the second encapsulation unit 912; the third protective layer 2313 includes a seventh protective portion 23131 corresponding to the third encapsulation unit 913; the fourth protective portion 23121 covers the first isolation groove 3011, the fifth protective portion 23122 covers the second isolation groove 3012, and the seventh protective portion 23131 covers the third isolation groove 3013; the fourth protective portion 23121 is located on a side of the first protective portion 23111 away from the substrate 1, the fifth protective portion 23122 is located on a side of the second protective portion 23112 away from the substrate 1, and the seventh protective portion 23131 is located on a side of the third protective portion 23113 away from the substrate 1.

In this way, the fourth protective portion 23121 and the first protective portion 23111 jointly protect the first isolation groove 3011, the fifth protective portion 23122 and the second protective portion 23112 jointly protect the second isolation groove 3012, and the seventh protective portion 23131 and the third protective portion 23113 jointly protect the third isolation groove 3013, thereby further improving the protective effect on the first isolation groove 3011, the second isolation groove 3012, and the third isolation groove 3013.

In some embodiments, the first isolation groove 3011 and the third isolation groove 3013 are located between the first light-emitting unit and the third light-emitting unit, and the third protection portion 23113 and the first protection portion 23111 are formed into one piece.

In some embodiments, the third protective layer 2313 and the third encapsulation unit 913 are provided in a same layer and made of a same material.

In this embodiment, the third protective layer 2313 can be formed simultaneously with the third encapsulation unit 913, thereby eliminating a specific process of forming the third protective layer 2313.

Each of the above different embodiments can enable the protective layer 231 to more effectively protect the corresponding isolation groove 301, making the isolation structure 3 at the isolation groove 301 less prone to over-etching, thereby further making the light-emitting unit 7 less prone to encapsulation failure.

In some embodiments, referring to FIG. 21, a fifth groove 901 is provided on a surface of the protective layer 231 away from the substrate 1, and an orthographic projection of the fifth groove 901 on the substrate corresponds to the orthographic projection of the isolation groove 301 on the substrate.

Since the isolation groove 301 is formed on the surface of the isolation structure 3 away from the substrate, the protective layer 231 located on the side of the isolation structure 3 away from the substrate recesses towards the substrate 1 at the isolation groove 301. Therefore, the fifth groove 901 is formed at the encapsulation unit 91 corresponding to the isolation groove 301, and the fifth groove 901 and the isolation groove 301 have a similar shape.

In some possible embodiments, referring to FIG. 22, the isolation structure 3 includes a first isolation portion 31 and a second isolation portion 32 that are sequentially stacked along a direction away from the substrate. An orthographic projection of a side of the first isolation portion 31 away from the substrate on the substrate is located in the orthographic projection of the second isolation portion 32 on the substrate. The isolation groove 301 is located on a surface of the second isolation portion 32 away from the substrate. A third groove 311 is provided on a surface of the first isolation portion 31 away from the substrate, and the orthographic projection of the isolation groove 301 on the substrate is located in the orthographic projection of the third groove 311 on the substrate.

Since the second isolation portion 32 is located on the side of the first isolation portion 31 away from the substrate, and a lateral width of the second isolation portion 32 is greater than a lateral width of the first isolation portion 31, the second isolation portion 32 causes the light-emitting functional layer and the second electrode layer to be disconnected at the isolation structure 3. In this way, the isolation structure 3 formed by the first isolation portion 31 and the second isolation portion 32 can more easily enable each light-emitting unit 7 to be independently encapsulated, thereby improving the encapsulation yield of the display panel.

The third groove 311 is naturally formed on the surface of the first isolation portion 31 away from the substrate at the second groove 202 on the pixel defining layer 2, and the isolation groove 301 is naturally formed on the surface of the second isolation portion 32 away from the substrate at the third groove 311. Therefore, the orthographic projection of the isolation groove 301 on the substrate is located in the orthographic projection of the third groove 311 on the substrate.

In some embodiments, still referring to FIG. 22, the orthographic projection of the via 131 on the substrate is located at a side of the orthographic projection of the first isolation portion 31 on the substrate close to the corresponding light-emitting unit.

For example, the first light-emitting unit and the second light-emitting unit are adjacent to each other, and a distance between the via 131 corresponding to the second light-emitting unit and the second light-emitting unit is smaller than a distance between the via 131 corresponding to the second light-emitting unit and the first light-emitting unit. In this way, the encapsulation unit 91 corresponding to the second light-emitting unit can cover the corresponding via 131 by extending a shorter distance, thereby better protecting the isolation structure at the corresponding isolation groove 301.

In some embodiments, a distance D3 between the orthographic projection of the via 131 on the substrate and the orthographic projection of an edge of an end surface of the corresponding first isolation portion 31 away from the substrate on the substrate is greater than 0.5 μm.

For example, in FIG. 22, the end surface of the first isolation portion 31 away from the substrate has two edges, a distance between the via 131 and one edge of the end surface of the corresponding first isolation portion 31 away from the substrate is the distance D3, and a distance between the via 131 and the other edge of the end surface of the first isolation portion 31 away from the substrate is a distance D4.

In this embodiment, the distance between the orthographic projection of the via 131 on the substrate and the orthographic projection of the edge of the end surface of the corresponding first isolation portion 31 away from the substrate on the substrate refers to the smaller distance D3 of distances between the via 131 and the edges of the end surface of the first isolation portion 31 away from the substrate, and the distance D3 can be 0.6 μm, 0.7 μm, 0.8 μm, 0.9 μm, 1 μm, or the like. Reasonably setting the distance D3 can improve the protective effect of the encapsulation unit 91 on the corresponding isolation structure.

In some embodiments, still referring to FIG. 22, the second electrode 6 of the light-emitting unit 7 is electrically connected to the first isolation portion 31, the first isolation portion 31 includes a conductive material, and the second electrode 6 of the light-emitting unit 7 extends to contact a sidewall of the first isolation portion 31, thereby achieving electrical connection between the second electrode 6 of the light-emitting unit 7 and the first isolation portion 31.

In other embodiments, referring to FIG. 23, the isolation structure 3 includes a third isolation portion 33 located on a side of the first isolation portion 31 facing towards the substrate, a fourth groove 331 is provided on a surface of the third isolation portion 33 away from the substrate, the orthographic projection of the third groove 311 on the substrate is located in an orthographic projection of the fourth groove 331 on the substrate, and the orthographic projection of the fourth groove 331 on the substrate is located in the orthographic projection of the second groove 202 on the substrate.

The fourth groove 331 is naturally formed on the surface of the third isolation portion 33 away from the substrate at the second groove 202 on the pixel defining layer 2, and the third groove 311 is naturally formed on the surface of the first isolation portion 31 away from the substrate at the fourth groove 331. Therefore, the orthographic projection of the third groove 311 on the substrate is located in the orthographic projection of the fourth groove 331 on the substrate, and the orthographic projection of the fourth groove 331 on the substrate is located in the orthographic projection of the second groove 202 on the substrate.

Still referring to FIG. 23, the second electrode 6 of the light-emitting unit 7 is electrically connected to the third isolation portion 33, the third isolation portion 33 includes a conductive material, and the second electrode 6 corresponding to the light-emitting unit 7 extends to contact the sidewall of the third isolation portion 33 to realize the electrical connection between the second electrode 6 of the light-emitting unit 7 and the third isolation portion 33.

Specifically, the material of the third isolation portion 33 includes molybdenum metal; and/or, the material of the first isolation portion 31 includes aluminum metal, and/or, the material of the second isolation portion 32 includes titanium metal. In this way, when the isolation structure 3 partitions the second electrode layer into the second electrode 6, the second electrode 6 is electrically connected to the first isolation portion 31 and/or the third isolation portion 33 more easily.

In some possible embodiments, still referring to FIG. 23, multiple encapsulation units 91 are arranged at intervals on a side of the isolation structure 3 away from the substrate, a gap is formed between at least one of the encapsulation units 91 located on the side of the isolation structure 3 away from the substrate and the surface of the isolation structure 3 away from the substrate, and the orthographic projection of the encapsulation unit 91 on the substrate covers the orthographic projection of the isolation opening 8 on the substrate and covers the orthographic projection of at least one of the isolation structures 3 on the substrate.

During the patterning process of the light-emitting unit 7, the encapsulation unit 91 is disconnected at the isolation structure 3 to form the encapsulation unit 91, and the encapsulation unit 91 can completely and independently encapsulate the corresponding light-emitting unit 7, thereby improving the display characteristics of the display panel.

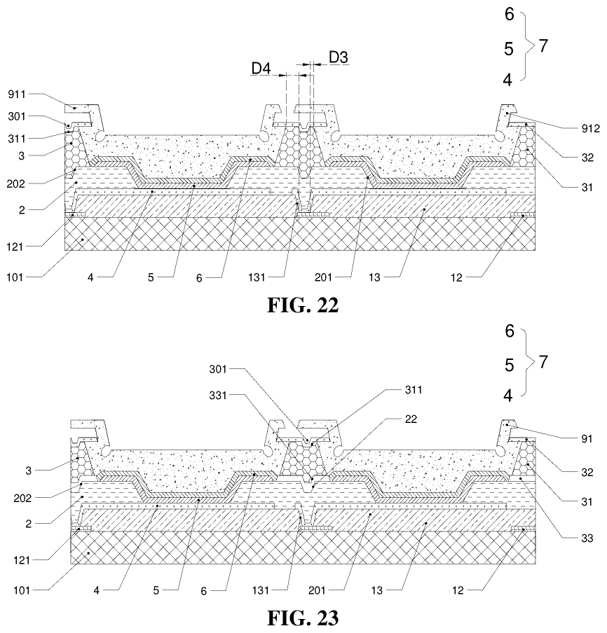

In some possible embodiments, referring to FIG. 24, the display panel includes a second encapsulation layer 14 located on a side of the encapsulation unit 91 away from the substrate, and a third encapsulation layer 15 located on a side of the second encapsulation layer 14 away from the substrate, materials of the encapsulation unit 91 and the third encapsulation layer 15 each include an inorganic material, and a material of the second encapsulation layer 14 includes an organic material.

For example, the encapsulation unit 91 and the third encapsulation layer 15 can be formed by chemical vapor deposition (CVD), and the second encapsulation layer 14 can be formed by ink-jet printing (IJP). The second encapsulation layer 14 and the third encapsulation layer 15 can better encapsulate the light-emitting unit 7, and thus the encapsulation quality of the display panel can be further improved.

In some possible embodiments, still referring to FIG. 2, a display panel includes a substrate 1, an isolation structure 3, a light emitting unit 7, an encapsulation unit 91, and a protective portion 9001.

The isolation structure 3 is located on a side of the substrate 1. The isolation structure 3 surrounds an isolation opening 8. An isolation groove 301 is provided on a surface of the isolation structure 3 away from the substrate 1. At least part of the light-emitting unit 7 is located in the isolation opening 8.

The encapsulation unit 91 is located on a side of the light emitting unit 7 away from the substrate 1.

The protective portion 9001 is located on a side of the isolation structure 3 away from the substrate 1 and is connected to the encapsulation unit 91. An orthographic projection of the protective portion 9001 on the substrate 1 covers at least part of an orthographic projection of the isolation groove 301 on the substrate 1.

The protective portion 9001 can be formed simultaneously with the encapsulation unit 91. The protective portion 9001 can protect the isolation structure 3 at the isolation groove 301 and play an etch blocking role for the isolation structure 3 at the isolation groove 301, so that the isolation structure 3 at the isolation groove 301 corresponding to the light-emitting unit is less prone to over-etching, thereby making it less likely to damage the encapsulation unit 91 corresponding to the light-emitting unit, and less likely to cause the encapsulation failure of the light-emitting unit.

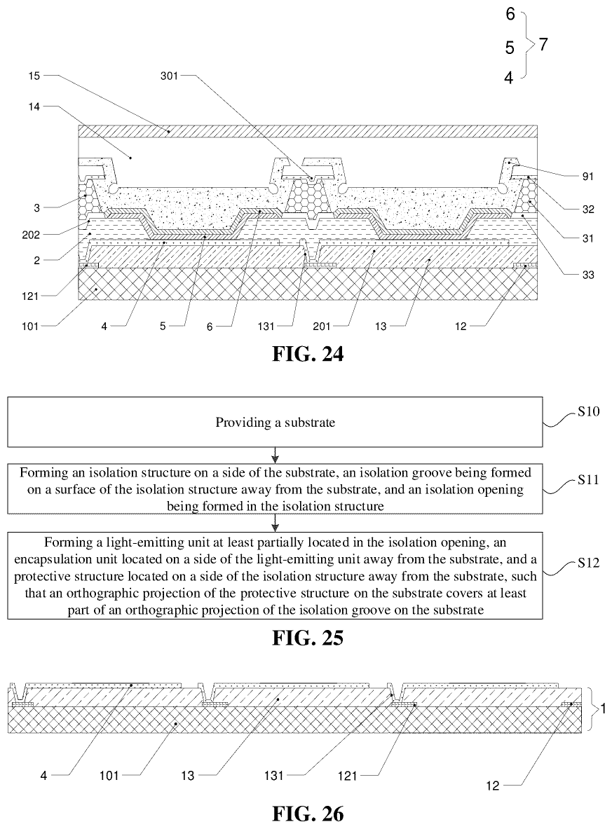

In some possible embodiments, referring to FIG. 25, the present disclosure provides a method for manufacturing a display panel, including:
S10, providing a substrate;
S11, forming an isolation structure on a side of the substrate, an isolation groove being formed on a surface of the isolation structure away from the substrate, and an isolation opening being provided in the isolation structure; and
S12, forming a light-emitting unit at least partially located in the isolation opening, an encapsulation unit located on a side of the light-emitting unit away from the substrate, and a protective structure located on a side of the isolation structure away from the substrate, such that an orthographic projection of the protective structure on the substrate covers at least part of an orthographic projection of the isolation groove on the substrate.

The light-emitting units 7 include a first light-emitting unit, a second light-emitting unit, and a third light-emitting unit, and the isolation openings 8 include a first isolation opening 81, a second isolation opening 82, and a third isolation opening 83.

Referring to FIG. 26, the substrate includes a base substrate 101, a circuit structure layer 12 is formed on a side of the base substrate 101 and includes multiple circuit structures 121 arranged at intervals, an insulation layer 13 is formed on a side of the circuit structure layer 12 away from the substrate, a via 131 exposing at least part of the circuit structure 121 is formed in the insulation layer 13, a first electrode layer is formed on a side of the insulation layer 13 away from the substrate 1 and includes multiple first electrodes 4 arranged at intervals, and the first electrode 4 is electrically connected to the circuit structure 121 through the via 131.

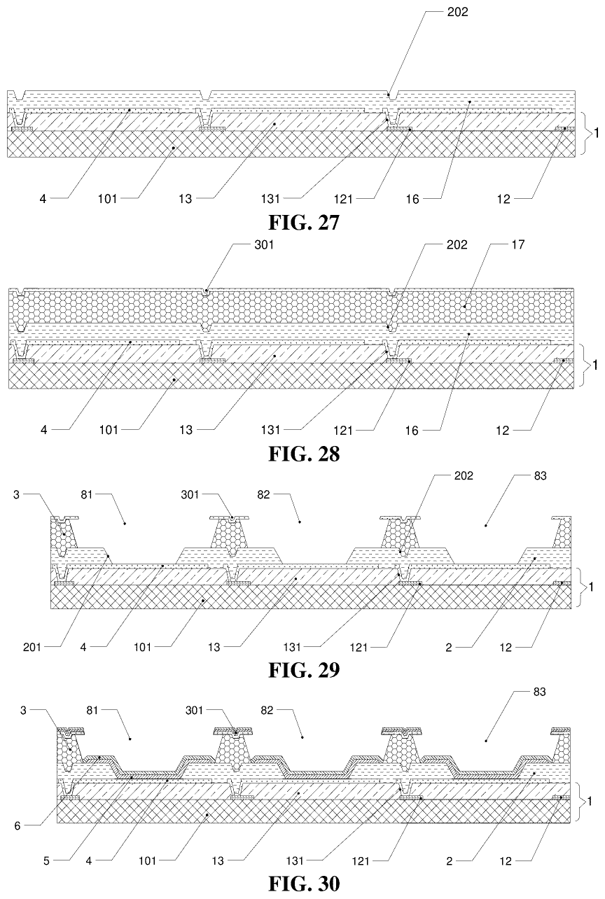

Referring to FIG. 27, a pixel defining material layer 16 is formed on a side of the first electrode layer away from the substrate 1, and a second groove 202 is formed on a surface of the pixel defining material layer 16 away from the substrate 1 at a position corresponding to the via 131.

Referring to FIG. 28, an isolation material layer 17 is formed on a side of the pixel defining material layer 16 away from the substrate, and an isolation groove 301 is formed on a surface of the isolation material layer 17 away from the substrate at a position corresponding to the second groove 202.

Referring to FIG. 29, the isolation material layer 17 and the pixel defining material layer 16 are sequentially patterned to form the isolation structure 3 and the pixel defining layer 2, and the isolation groove 301 is located on the surface of the isolation structure 3 away from the substrate, and the second groove 202 is located on the surface of the pixel defining layer 2 away from the substrate.

Different embodiments in which the light-emitting unit 7 and the corresponding encapsulation unit 91 are formed are described in detail below.

In a first embodiment, referring to FIG. 30, a first light-emitting material layer partially located in the first isolation opening 81 is formed, the first light-emitting material layer extends into the second isolation opening 82 and the third isolation opening 83, and the first light-emitting material layer includes a light-emitting functional layer and a second electrode layer of the first light-emitting unit that are sequentially stacked along a direction away from the substrate.

The light-emitting functional layer is disconnected at the isolation structure 3, so that at least part of the light-emitting functional layer is located in the isolation opening 8 to form the light-emitting portion 5. By controlling an evaporation angle, the light-emitting portion 5 can be not in contact with the isolation structure 3.

The second electrode layer is disconnected at the isolation structure 3, so that at least part of the second electrode layer is located in the isolation opening 8 to form the second electrode 6. By controlling the evaporation angle, the second electrode 6 can extend from the isolation opening 8 to be in electrical contact with the isolation structure 3, thereby connecting adjacent second electrodes 6 or connecting the second electrode 6 to other circuits. In this way, the manufacturing difficulty of the display panel can be reduced.

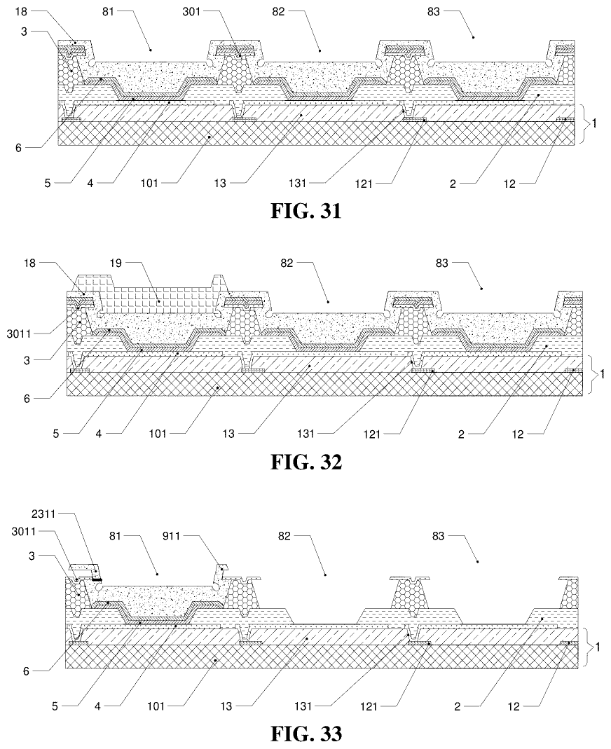

Referring to FIG. 31, a first encapsulation unit material layer 18 is formed on a side of the first light-emitting material layer away from the substrate.

Referring to FIG. 32, a first etching protective layer 19 is formed on a side of the first encapsulation unit material layer 18 located on the first light-emitting unit away from the substrate 1, and an orthographic projection of the first etching protective layer 19 on the substrate 1 covers an orthographic projection of a first isolation groove 3011 on the isolation structure 3 corresponding to the first light-emitting unit on the substrate 1.

The first etching protective layer 19 can protect the light-emitting functional layer, the second electrode layer, and the first encapsulation unit material layer 18 of the first light-emitting unit.

Referring to FIG. 33, the first encapsulation unit material layer 18 and the first light-emitting material layer that are not covered by the first etching protective layer 19 are etched to be removed, and then the first etching protective layer 19 is removed to form the light-emitting portion 5 of the first light-emitting unit, the second electrode 6, the first encapsulation unit 911, and the first protective layer 2311 that are at least partially formed in the first isolation opening 81; an orthographic projection of the first protective layer 2311 on the substrate covers the orthographic projection of the first isolation groove 3011 on the substrate 1, and the first protective layer 2311 is connected to the first encapsulation unit 911.

After the first encapsulation unit material layer 18, the light-emitting functional layer, and the second electrode layer that are not covered by the first etching protective layer 19 are removed, the first electrode 4, the light-emitting portion 5 of the first light-emitting unit, and the second electrode 6 form the first light-emitting unit, and the first light-emitting unit is entirely covered by the encapsulation unit 91, thereby reducing the risks of equipment contamination and layer disconnection caused by the vapor deposition material entering the vapor deposition apparatus after being exposed to air.

In this way, in a condition without a fine metal mask, the light-emitting portion 5, the second electrode 6, and the encapsulation unit 91 can be formed in only the first isolation opening 81 corresponding to the first light-emitting unit, and the second electrode 6 can be electrically connected to the isolation structure 3, thereby forming the first light-emitting unit in the first isolation opening 81 corresponding to the first light-emitting unit at a low cost.

Since the orthographic projection of the first etch protection layer 19 on the substrate 1 covers the orthographic projection of the first isolation groove 3011 on the substrate, the orthographic projection of the first protective layer 2311 on the substrate 1 covers the orthographic projection of the first isolation groove 3011 on the substrate 1.

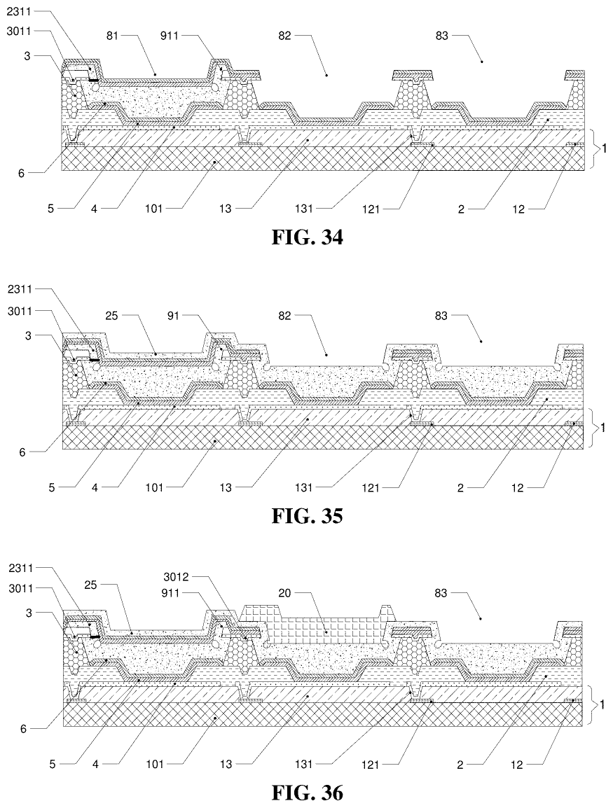

Referring to FIG. 34, a second light-emitting material layer partially located in the second isolation opening 82 is formed, the second light-emitting material layer extends to a side of the first light-emitting unit away from the substrate and into the third isolation opening 83, and the second light-emitting material layer includes a light-emitting functional layer and a second electrode layer of the second light-emitting unit that are sequentially stacked along a direction away from the substrate.

Referring to FIG. 35, a second encapsulation unit material layer 25 is formed on a side of the second light-emitting material layer away from the substrate.

Referring to FIG. 36, a second etching protective layer 20 is formed on a side of the second encapsulation unit material layer 25 of the second light-emitting unit away from the substrate, and the second etching protective layer 20 covers the second light-emitting unit and the second isolation groove 3012.

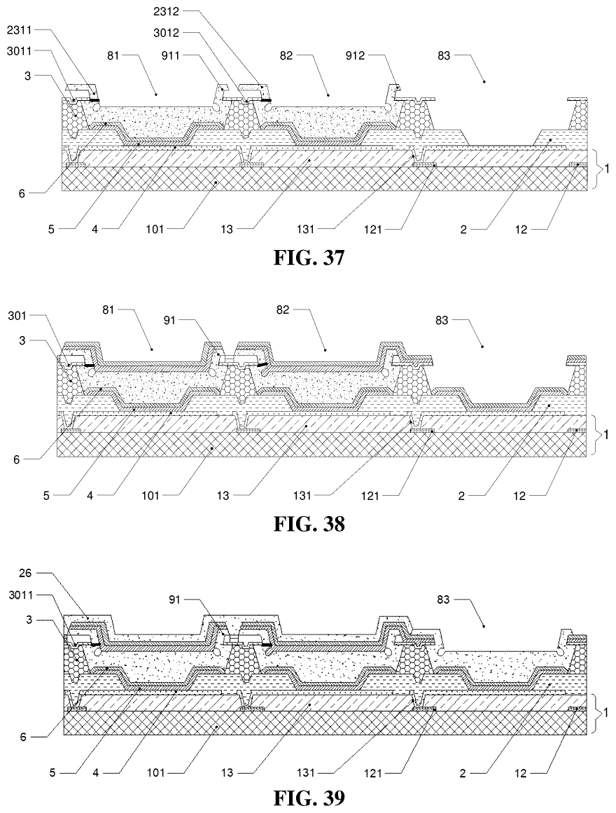

Referring to FIG. 37, the second encapsulation unit material layer 25 and the second light-emitting material layer that are not covered by the second etching protective layer 20 are removed, the second etching protective layer 20 is removed, and then the light-emitting portion 5 of the second light-emitting unit, the second electrode 6, and the second encapsulation unit 912, and the second protective layer 2312 are formed in the second isolation opening 82; an orthographic projection of the second protective layer 2312 on the substrate covers an orthographic projection of a second isolation groove 3012 on the substrate 1, and the second protective layer 2312 is connected to the second encapsulation unit 912.

Since the orthographic projection of the first protective layer 2311 on the substrate 1 covers the orthographic projection of the first isolation groove 3011 on the substrate 1, during the process of removing the second encapsulation unit material layer 25 and the second light-emitting material layer that are not covered by the second etching protective layer 20, the first protective layer 2311 can protect the isolation structure 3 at the first isolation groove 3011, making the isolation structure 3 at the first isolation groove 3011 less prone to over-etching, thereby making it less likely to damage the first encapsulation unit 911, and thus improving the encapsulation performance of the first light-emitting unit.

Since the orthographic projection of the second etching protective layer 20 on the substrate 1 covers the orthographic projection of the second isolation groove 3012 on the substrate 1, the orthographic projection of the second protective layer 2312 on the substrate 1 covers the orthographic projection of the second isolation groove 3012 on the substrate 1.

Referring to FIG. 38, a third light-emitting material layer partially formed in the third isolation opening 83 is formed, the third light-emitting material layer extends to a side of the first light-emitting unit away from the substrate and a side of the second light-emitting unit away from the substrate; the third light-emitting material layer includes a light-emitting functional layer and a second electrode layer of the third light-emitting unit that are sequentially stacked along the direction away from the substrate.

Referring to FIG. 39, a third encapsulation unit material layer 26 is formed on a side of the third light-emitting material layer away from the substrate.

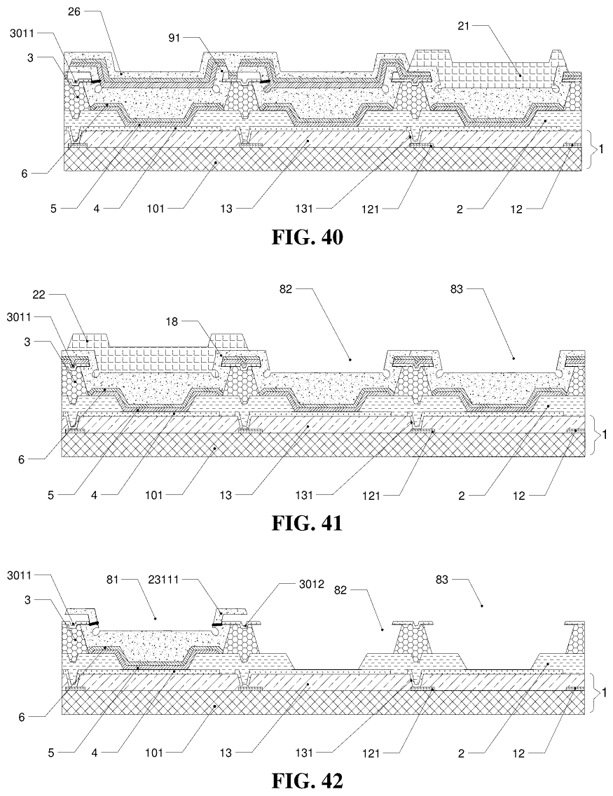

Referring to FIG. 40, a third etching protective layer 21 is formed on a side of the third encapsulation unit material layer 26 of the third light-emitting unit away from the substrate 1, and an orthographic projection of the third etching protective layer 21 on the substrate covers orthographic projections of the third light-emitting unit and a third isolation groove 3013 on the substrate 1.

Referring to FIG. 7 again, the third encapsulation unit material layer 26 and the third light-emitting material layer that are not covered by the third etching protective layer 21 are removed, the third etching protective layer 21 is removed, and then the light-emitting portion 5, the second electrode 6, the third encapsulation unit 913, and a third protective layer 2313 that correspond to the third light-emitting unit are formed in the third isolation opening 83, and an orthographic projection of the third protective layer 2313 on the substrate covers the orthographic projection of the third isolation groove 3013 on the substrate 1.

Since the orthographic projection of the first protective layer 2311 on the substrate covers the orthographic projection of the first isolation groove 3011 on the substrate 1, and the orthographic projection of the second protective layer 2312 on the substrate covers the orthographic projection of the second isolation groove 3012 on the substrate 1, during the process of removing the second encapsulation unit material layer and the third light-emitting material layer that are not covered by the third etching protective layer 21, the first protective layer 2311 can protect the isolation structure 3 at the first isolation groove 3011, and the second protective layer 2312 can protect the isolation structure 3 at the second isolation groove 3012, making the isolation structures 3 at the first isolation groove 3011 and the second isolation groove 3012 less prone to over-etching, thereby making it less likely to damage the encapsulation units 91 respectively corresponding to the first light-emitting unit and the second light-emitting unit, and thus improving the encapsulation performance of the first light-emitting unit and the second light-emitting unit.

Since the third etching protective layer 21 covers the third isolation groove 3013, the orthographic projection of the third protective layer 2313 on the substrate covers the orthographic projection of the third isolation groove 3013 on the substrate 1. The third protective layer 2313 can protect the isolation structure 3 at the third isolation groove 3013, thereby improving the encapsulation performance of the third light-emitting unit.

In this embodiment, in the display panel formed by the above method, the orthographic projection of the protective layer of the encapsulation unit 91 corresponding to each type of light-emitting unit 7 on the substrate 1 covers the orthographic projection of the isolation groove 301 corresponding to this light-emitting unit 7 on the substrate, making the isolation structure 3 at the isolation groove 301 corresponding to the light-emitting unit 7 less prone to over-etching, thereby making it less likely to damage the encapsulation unit 91 of the light-emitting unit 7, and thus improving the encapsulation performance of the light-emitting unit 7, and ultimately improving the display effect of the display panel.

In a second embodiment, referring to FIG. 41, the first light-emitting material layer, the first encapsulation unit material layer, and a fourth etching protective layer 22 are sequentially formed in the first isolation opening 81 along the direction away from the substrate, and an orthographic projection of the fourth etching protective layer 22 on the substrate covers the orthographic projections of the first light-emitting unit, the first isolation groove 3011, and the second isolation groove 3012 on the substrate 1.

Referring to FIG. 42, the first encapsulation unit material layer and the first light-emitting material layer that are not covered by the fourth etching protective layer 22 are removed, and then the fourth etching protective layer 22 is removed, so that the light-emitting portion of the first light-emitting unit, the second electrode, the first encapsulation unit 911, and a first protective portion 23111 of the first protective layer 2311 are formed in the first isolation opening 81, and an orthographic projection of the first protective portion 23111 of the first protective layer 2311 on the substrate covers the orthographic projections of the first isolation groove 3011 and the second isolation groove 3012 on the substrate 1.

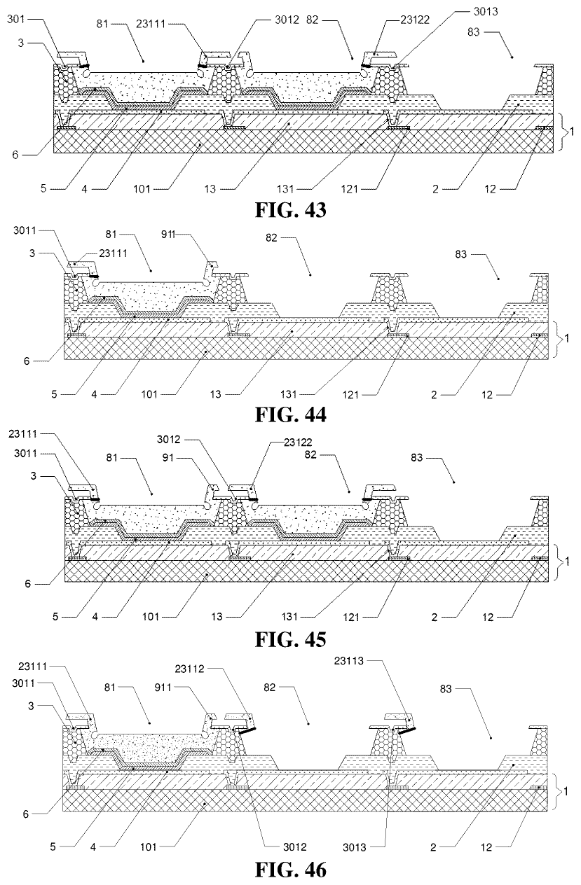

Referring to FIG. 43, a second light-emitting unit, and a second encapsulation unit 912 and a fifth protective portion 23122 of the second protective layer 2312 that are located on a side of the second light-emitting unit away from the substrate are formed in the second isolation opening 82; an orthographic projection of the fifth protective portion 23122 of the second protective layer 2312 on the substrate covers the orthographic projection of the third isolation groove 3013 on the substrate 1.

In this embodiment, in the display panel formed by the above method, the orthographic projection of the first protective portion 23111 on the substrate covers the orthographic projections of the first isolation groove 3011 and the second isolation groove 3012 on the substrate 1, and the orthographic projection of the fifth protective portion 23122 on the substrate covers the orthographic projection of the third isolation groove 3013 on the substrate 1, making the isolation structure 3 at the isolation groove 301 corresponding to the light-emitting unit 7 less prone to over-etching, thereby making it less likely to damage the encapsulation unit 91 corresponding to the light-emitting unit 7, and thus improving the encapsulation performance of the light-emitting unit 7, ultimately improving the display effect of the display panel.

In a third embodiment, referring to FIG. 44, a first light-emitting unit at least partially in the first isolation opening 81, and a first encapsulation unit 911 and a first protective portion 23111 that are located on a side of the first light-emitting unit away from the substrate are formed, and an orthographic projection of the first protective portion 23111 on the substrate covers an orthographic projection of the first isolation groove 3011 on the substrate 1.

Referring to FIG. 45, a second light-emitting unit, and a second encapsulation unit 912 and a fifth protective portion 23122 that are located on a side of the second light-emitting unit away from the substrate 1 are formed in the second isolation opening 82, and an orthographic projection of the fifth protective portion 23122 on the substrate covers the orthographic projections of the second isolation groove 3012 and the third isolation groove 3013 on the substrate 1.

The third light-emitting unit, and a third encapsulation unit 913 located on a side of the third light-emitting unit away from the substrate are formed in the third isolation opening 83, and an orthographic projection of the encapsulation unit 91 of the third light-emitting unit on the substrate is located outside the orthographic projection of the isolation groove 301 on the substrate.

In this embodiment, in the display panel formed by the above method, the orthographic projection of the first protective portion 23111 on the substrate covers the orthographic projection of the first isolation groove 3011 on the substrate 1, and the orthographic projection of the fifth protective portion 23122 on the substrate covers the orthographic projections of the second isolation groove 3012 and the third isolation groove 3013 on the substrate, making the isolation structure 3 at the isolation groove 301 corresponding to the light-emitting unit 7 less prone to over-etching, thereby making it less likely to damage the encapsulation unit 91 corresponding to the light-emitting unit 7, and thus improving the encapsulation performance of the light-emitting unit 7, ultimately improving the display effect of the display panel.

In a fourth embodiment, referring to FIG. 46, a first light-emitting unit, and a first encapsulation unit 911, and a first protective portion 23111, a second protective portion 23112, and a third protective portion 23113 of the first protective layer 2311 that are located on a side of the first light-emitting unit away from the substrate are formed in the first isolation opening 81; an orthographic projection of the first protective portion 23111 on the substrate covers an orthographic projection of the first isolation groove 3011 on the substrate 1, an orthographic projection of the second protective portion 23112 on the substrate 1 covers an orthographic projection of the second isolation groove 3012 on the substrate 1, and an orthographic projection of the third protective portion 23113 on the substrate covers an orthographic projection of the third isolation groove 3013 on the substrate 1. The first protective portion 23111, the second protective portion 23112, and the third protective portion 23113 are provided in a same layer as the first encapsulation unit 911, and the first protective portion 23111, the second protective portion 23112, and the third protective portion 23113 can be formed simultaneously with the first encapsulation unit 911.

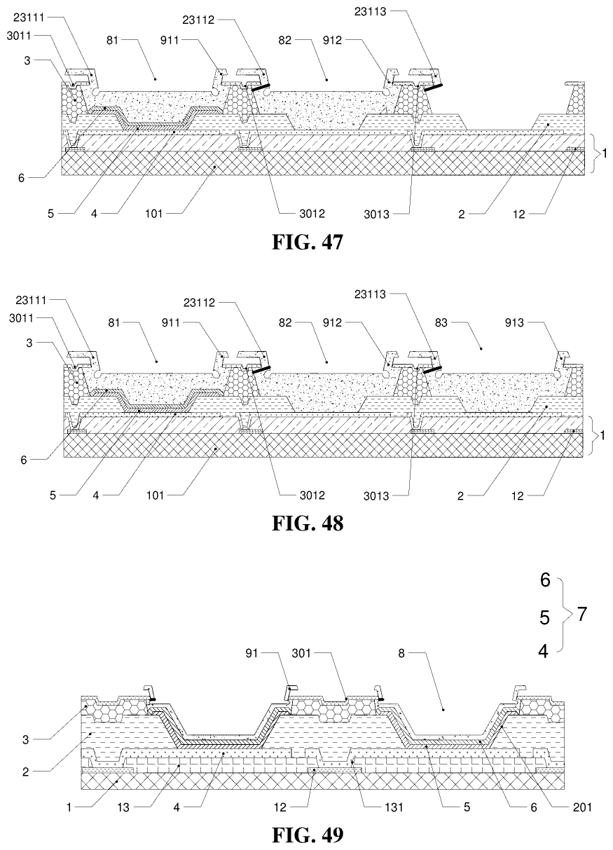

Referring to FIG. 47, a second light-emitting unit and a second encapsulation unit 912 located on a side of the second light-emitting unit away from the substrate are formed in the second isolation opening 82, and an orthographic projection of the second encapsulation unit 912 on the substrate 1 is located outside the orthographic projection of the second isolation groove 3012 on the substrate 1.

Referring to FIG. 48, a third light-emitting unit and a third encapsulation unit 913 located on a side of the third light-emitting unit away from the substrate are formed in the third isolation opening 83, and an orthographic projection of the third encapsulation unit 913 on the substrate 1 is located outside the orthographic projection of the third isolation groove 3013 on the substrate 1.

In this embodiment, in the display panel formed by the above method, the orthographic projections of the first protective portion 23111, the second protective portion 23112, and the third protective portion 23113 on the substrate cover the orthographic projections of the first isolation groove 3011, the second isolation groove 3012, and the third isolation groove 3013 on the substrate 1, respectively, making the isolation structure 3 at the isolation groove 301 corresponding to the light-emitting unit 7 less prone to over-etching, thereby making it less likely to damage the encapsulation unit 91 corresponding to the light-emitting unit 7, and thus improving the encapsulation performance of the light-emitting unit 7, ultimately improving the display effect of the display panel.

According to the above method concept, the orthographic projection of the first etching protective layer 19 on the substrate 1 can cover the orthographic projections of the corresponding second isolation groove 3012 and the third isolation groove 3013 on the substrate 1, ultimately forming the display panel as shown in FIGS. 15 to 17.

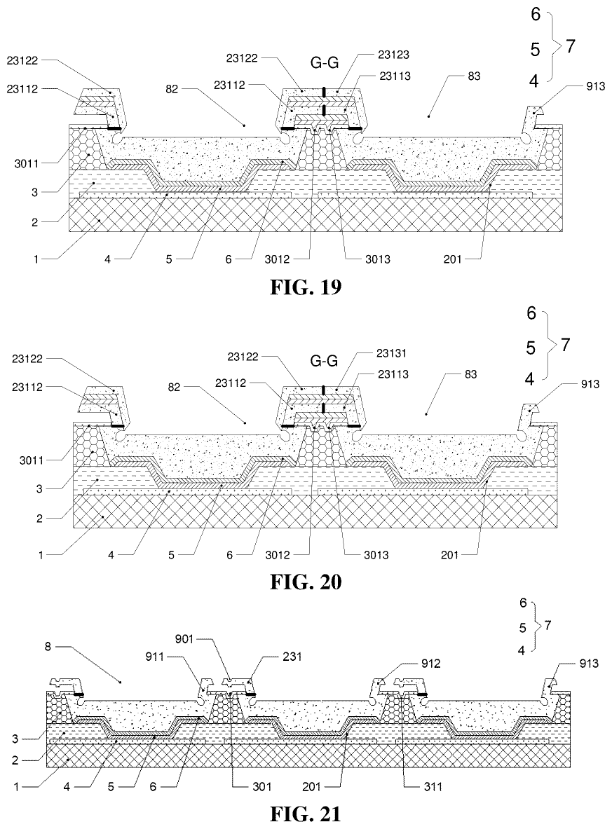

The orthographic projection of the second etching protective layer 20 on the substrate 1 can cover the orthographic projections of the corresponding second light-emitting unit, the first isolation groove 3011, the second isolation groove 3012, and the third isolation groove 3013 on the substrate 1, ultimately forming the display panel as shown in FIGS. 18 and 19.

In a possible embodiment, after the step of forming the light-emitting unit at least partially located in the isolation opening, the encapsulation unit 91 located on the side of the light-emitting unit away from the substrate 1, and the protective structure 23 located on the side of the isolation structure 3 away from the substrate 1, the method includes: removing the protective structure 23, ultimately forming the display panel as shown in FIG. 49.

In some possible embodiments, the present disclosure provides an electronic device including the display panel provided in the present disclosure, or including the display panel manufactured by the method for manufacturing the display panel in the present disclosure. The electronic device can include a device capable of processing images, such as a server, a personal computer, a notebook computer, and the like. Since the electronic device includes the display panel provided in the present disclosure, the encapsulation performance and the display quality of the electronic device are relatively good.

The technical features of the embodiments can be combined in any way, and in order to make the description clear, not all the possible combinations of the technical features in the above embodiments are described. However, as long as there is no contradiction when combining these technical features, they should be considered as falling within the scope recited in the present disclosure.

The embodiments described above represent only a few implementations of the present disclosure and description thereof is relatively specific and detailed, but are not to be construed as limiting the scope of the present disclosure. It should be noted that a person skilled in the art could also make several changes and modifications without departing from the concept of the present disclosure, which falls within the protection scope of the present disclosure. Therefore, the protection scope of the present disclosure should be subject to the appended claims.

What is claimed is:

1. A display panel, comprising:
a substrate;
an isolation structure, located on a side of the substrate, wherein the isolation structure surrounds an isolation opening, and at least one isolation groove is provided on a surface of the isolation structure away from the substrate;
at least one light-emitting unit, at least partially located in the isolation opening;
at least one encapsulation unit, located on a side of the at least one light-emitting unit away from the substrate; and
at least one protective structure, located on the side of the isolation structure away from the substrate, an orthographic projection of the at least one protective structure on the substrate covering at least part of an orthographic projection of the at least one isolation groove on the substrate.

2. The display panel according to claim 1, wherein
the at least one protective structure comprises at least one protective layer of the same material as the at least one encapsulation unit, an orthographic projection of the at least one isolation groove on the substrate being located in an orthographic projection of the at least one protective layer on the substrate; and
a minimum distance between an edge of the orthographic projection of the at least one isolation groove on the substrate and an edge of the orthographic projection of the at least one protective layer on the substrate is greater than or equal to 0 μm.

3. The display panel according to claim 2, wherein
the at least one protective structure further comprises a first auxiliary protective layer located between the protective layer and the isolation structure;
an orthographic projection of the first auxiliary protective layer on the substrate covers at least part of the orthographic projection of the at least one isolation groove on the substrate;
the at least one light-emitting unit comprises a first electrode, a light-emitting portion, and a second electrode that are sequentially stacked on a side of the substrate; and
a material of the first auxiliary protective layer is the same as a material of the light-emitting portion.

4. The display panel according to claim 3, wherein
the at least one protective structure further comprises a second auxiliary protective layer located between the protective layer and the first auxiliary protective layer;
an orthographic projection of the second auxiliary protective layer on the substrate covers at least part of the orthographic projection of the at least one isolation groove on the substrate; and
a material of the second auxiliary protective layer is the same as a material of the second electrode.

5. The display panel according to claim 1, wherein
the at least one light-emitting unit comprises a plurality of light-emitting units, the plurality of light-emitting units comprising a first light-emitting unit, a second light-emitting unit, and a third light-emitting unit;
the at least one encapsulation unit comprises a plurality of encapsulation units, the plurality of encapsulation units comprising a first encapsulation unit corresponding to the first light-emitting unit, a second encapsulation unit corresponding to the second light-emitting unit, and a third encapsulation unit corresponding to the third light-emitting unit;
the at least one protective layer comprises at least one type of protective layer corresponding to one of the first encapsulation unit, the second encapsulation unit, and the third encapsulation unit, respectively, one of the at least one type of protective layer covering the at least one isolation groove corresponding to one, two, or three of the first encapsulation unit, the second encapsulation unit, and the third encapsulation unit of the plurality of light-emitting units; and
the at least one protective layer comprises two types of protective layers corresponding to one of the first encapsulation unit, the second encapsulation unit, and the third encapsulation unit, the types of protective layers partially overlapping.

6. The display panel according to claim 1, wherein
the at least one light-emitting unit comprises a plurality of light-emitting units, the plurality of light-emitting units comprising a first light-emitting unit, a second light-emitting unit, and a third light-emitting unit;
the at least one encapsulation unit comprises a plurality of encapsulation units, the plurality of encapsulation units comprising a first encapsulation unit corresponding to the first light-emitting unit, a second encapsulation unit corresponding to the second light-emitting unit, and a third encapsulation unit corresponding to the third light-emitting unit; and
at least one isolation groove comprises a plurality of isolation grooves, the plurality of isolation grooves comprising a first isolation groove corresponding to the first light-emitting unit, a second isolation groove corresponding to the second light-emitting unit, and a third isolation groove corresponding to the third light-emitting unit.

7. The display panel according to claim 6, wherein the at least one protective layer comprises a plurality of protective layers, the plurality of protective layers comprising a first protective layer covering the first isolation groove, a second protective layer covering the second isolation groove, and a third protective layer covering the third isolation groove.

8. The display panel according to claim 6, wherein
the at least one protective layer comprises a first protective layer,
the first protective layer comprising:
a first protective portion corresponding to the first encapsulation unit and covering the first isolation groove,
a second protective portion corresponding to the second encapsulation unit and covering the second isolation groove, and
a third protective portion corresponding to the third encapsulation unit and covering the third isolation groove; and
the second isolation groove is located at a side of the second light-emitting unit close to the first light-emitting unit, and the first protective portion and the second protective portion are formed into one piece; or the second isolation groove is located at the side of the second light-emitting unit close to the first light-emitting unit, the third isolation groove is located at a side of the third light-emitting unit close to the first light-emitting unit, and the first protective portion, the second protective portion, and the third protective portion are formed into one piece.

9. The display panel according to claim 8, wherein
the at least one protective layer comprises a plurality of protective layers further comprising a second protective layer,
the second protective layer comprising a fourth protective portion corresponding to the first encapsulation unit, a fifth protective portion corresponding to the second encapsulation unit, and a sixth protective portion corresponding to the third encapsulation unit;
the fourth protective portion covering the first isolation groove, the fifth protective portion covering the second isolation groove, and the sixth protective portion covering the third isolation groove; and
the fourth protective portion being located on a side of the first protective portion away from the substrate, the fifth protective portion being located on a side of the second protective portion away from the substrate, and the sixth protective portion being located on a side of the third protective portion away from the substrate; and
the second isolation groove is located at the side of the second light-emitting unit close to the first light-emitting unit, and the fourth protective portion and the fifth protective portion are formed into one piece; or the second isolation groove is located at the side of the second light-emitting unit close to the first light-emitting unit, the third isolation groove is located at the side of the third light-emitting unit close to the first light-emitting unit, and the fourth protective portion, the fifth protective portion, and the sixth protective portion are formed into one piece.

10. The display panel according to claim 8, wherein
the at least one protective layer comprises a plurality of protective layers further comprising a second protective layer and a third protective layer,
the second protective layer comprising:
a fourth protective portion corresponding to the first encapsulation unit, covering the first isolation groove, and located on a side of the first protective portion away from the substrate, and
a fifth protective portion corresponding to the second encapsulation unit, covering the second isolation groove, and located on a side of the second protective portion away from the substrate; and
the third protective layer comprising a seventh protective portion corresponding to the third encapsulation unit, covering the third isolation groove and located on a side of the third protective portion away from the substrate.

11. The display panel according to claim 6, wherein
the at least one protective layer comprises a first protective layer,
the first protective layer comprising:
a first protective portion corresponding to the first encapsulation unit and covering the first isolation groove and the second isolation groove, and
a second protective portion corresponding to the second encapsulation unit and covering the third isolation groove.

12. The display panel according to claim 6, wherein
the at least one protective layer comprises a first protective layer,
the first protective layer comprising:
a first protective portion corresponding to the first encapsulation unit and covering the first isolation groove,
a second protective portion corresponding to the second encapsulation unit and covering the second isolation groove and the third isolation groove.

13. The display panel according to claim 6, wherein
the at least one protective layer comprises a first protective layer,
the first protective layer comprising:
a first protective portion corresponding to the first encapsulation unit and covering the first isolation groove, the second isolation groove, and the third isolation groove.

14. The display panel according to claim 1, wherein
the substrate comprises:
a base substrate,
a circuit structure layer comprising a circuit structure, and
an insulation layer located on a side of the substrate and provided with a via penetrating through the insulation layer;
the at least one light-emitting unit comprises a first electrode electrically connected to the circuit structure through the via;
the orthographic projection of the at least one isolation groove on the substrate is located within an orthographic projection of the via on the substrate;
the display panel further comprises a pixel defining layer located between the insulation layer and the isolation structure, a second groove is provided on a surface of the pixel defining layer away from the substrate, and the orthographic projection of the at least one isolation groove on the substrate is located within an orthographic projection of the second groove on the substrate; and
a fifth groove is provided on a surface of the at least one protective layer away from the substrate, and an orthographic projection of the fifth groove on the substrate corresponds to the orthographic projection of the at least one isolation groove on the substrate.

15. The display panel according to claim 14, wherein
the isolation structure comprises a first isolation portion and a second isolation portion that are stacked along a direction away from the substrate, an orthographic projection of a surface of the first isolation portion away from the substrate on the substrate being located within an orthographic projection of the second isolation portion on the substrate, and the at least one isolation groove being located on a surface of the second isolation portion away from the substrate; and
the orthographic projection of the via on the substrate is located within an orthographic projection of the first isolation portion on the substrate and is close to a side of a corresponding one of the at least one light-emitting unit.

16. A display panel, comprising:
a substrate;
an isolation structure, located on a side of the substrate, wherein the isolation structure surrounds an isolation opening, and at least one isolation groove is provided on a side of the isolation structure away from the substrate;
at least one light-emitting unit, at least partially located in the isolation opening;
at least one encapsulation unit, located on a side of the at least one light-emitting unit away from the substrate; and
a protective portion, located on the side of the isolation structure away from the substrate and connected to the at least one encapsulation unit, an orthographic projection of the protective portion on the substrate covering at least part of an orthographic projection of the at least one isolation groove on the substrate.

17. A method for manufacturing a display panel, comprising:
providing a substrate;
forming an isolation structure on a side of the substrate, at least one isolation groove being formed on a surface of the isolation structure away from the substrate, and at least one isolation opening being provided in the isolation structure; and
forming at least one light-emitting unit at least partially located in the at least one isolation opening, at least one encapsulation unit located on a side of the at least one light-emitting unit away from the substrate, and at least one protective structure located on the side of the isolation structure away from the substrate, such that an orthographic projection of the at least one protective structure on the substrate covers at least part of an orthographic projection of the at least one isolation groove on the substrate.

18. The method for manufacturing the display panel according to claim 17, wherein the forming the at least one light-emitting unit at least partially located in the at least one isolation opening, the at least one encapsulation unit located on the side of the at least one light-emitting unit away from the substrate, and the at least one protective structure located on the side of the isolation structure away from the substrate comprises:
forming a first light-emitting material layer partially located in a first isolation opening of the at least one isolation opening, the first light-emitting material layer comprising a light-emitting functional layer and a second electrode layer;
forming a first encapsulation unit material layer on a side of the first light-emitting material layer away from the substrate;
forming a patterned first etching protective layer on a side of the first encapsulation unit material layer of the corresponding first light-emitting unit away from the substrate, an orthographic projection of the first etching protective layer on the substrate covering an orthographic projection of a corresponding one of the at least one first light-emitting unit and an orthographic projection of a first isolation groove on the substrate; and
etching to remove part of the first encapsulation unit material layer and part of the first light-emitting material layer that are not covered by the first etch protective layer, and then removing the first etching protective layer, to form a light-emitting portion of the first light-emitting unit, a second electrode, a first encapsulation unit, and a first protective layer that are at least partially located within the first isolation opening, a first encapsulation unit, and a first protective layer that are at least partially located in the first isolation opening, an orthographic projection of the first protective layer on the substrate covering the orthographic projection of the first isolation groove on the substrate.

19. The method for manufacturing the display panel according to claim 18, wherein
the orthographic projection of the first etching protective layer on the substrate further covers orthographic projections of a corresponding second isolation groove and a corresponding third isolation groove on the substrate;
the first protective layer comprises a first protective portion, a second protective portion, and a third protective portion; an orthographic projection of the first protective portion on the substrate covers the orthographic projection of the first isolation groove on the substrate, an orthographic projection of the second protective portion on the substrate covers an orthographic projection of the second isolation groove on the substrate, and an orthographic projection of the third protective portion on the substrate covers the orthographic projection of the third isolation groove on the substrate; and
at least two of the first protective portion, the second protective portion, or the third protective portion are formed into one piece.

20. The method for manufacturing the display panel according to claim 19, after the etching to remove the part of the first encapsulation unit material layer and the part of the first light-emitting material layer that are not covered by the first etching protective layer, and removing the first etching protective layer, further comprising:
forming a second light-emitting material layer partially located in a second isolation opening;
forming a second encapsulation unit material layer on a side of the second light-emitting material layer away from the substrate;
forming a patterned second etching protective layer on the side of the second encapsulation unit material layer away from the substrate, an orthographic projection of the second etching protective layer on the substrate covering orthographic projections of a corresponding second light-emitting unit, the first isolation groove, the second isolation groove, and the third isolation groove on the substrate; and
etching to remove the second encapsulation unit material layer and the second light-emitting material layer that are not covered by the second etching protective layer, and then removing the second etching protective layer, to form a light-emitting portion of the second light-emitting unit, a second electrode, a second encapsulation unit, and a second protective layer that are at least partially located in the second isolation opening;
wherein
the second protective layer comprises a fourth protective portion, a fifth protective portion, and a sixth protective portion,
an orthographic projection of the fourth protective portion on the substrate covering the orthographic projection of the first isolation groove on the substrate,
an orthographic projection of the fifth protective portion on the substrate covering the orthographic projection of the second isolation groove on the substrate, and
an orthographic projection of the sixth protective portion on the substrate covering the orthographic projection of the third isolation groove on the substrate; and
the fourth protective portion overlaps the first protective portion, the fifth protective portion overlaps the second protective portion, and the sixth protective portion overlaps the third protective portion.

21. The method for manufacturing the display panel according to claim 17, wherein
the at least one light-emitting unit comprises a plurality of light-emitting units, the plurality of light-emitting units comprising a first light-emitting unit, a second light-emitting unit, and a third light-emitting unit;
the at least one isolation opening comprises a plurality of isolation openings, the plurality of isolation openings comprising a first isolation opening, a second isolation opening, and a third isolation opening;
the at least one isolation groove comprises a plurality of isolation grooves, the plurality of the isolation grooves comprising a first isolation groove corresponding to the first light-emitting unit, a second isolation groove corresponding to the second light-emitting unit, and a third isolation groove corresponding to the third light-emitting unit; and
the forming the at least one light-emitting unit at least partially located in the at least one isolation opening, the at least one encapsulation unit located on the side of the at least one light-emitting unit away from the substrate, and the at least one protective structure located on the side of the isolation structure away from the substrate comprises:
forming a first light-emitting material layer partially located in the first isolation opening, a first encapsulation unit material layer, and a patterned fourth etching protective layer, an orthographic projection of the fourth etching protective layer on the substrate covering orthographic projections of the corresponding first light-emitting unit, the first isolation groove, and the second isolation groove on the substrate,
etching to remove the first encapsulation unit material layer and the first light-emitting material layer that are not covered by the fourth etching protective layer, and then removing the fourth etching protective layer, to form a light-emitting portion of the first light-emitting unit, a second electrode, a first encapsulation unit, and a first protective layer that are at least partially located in the first isolation opening, an orthographic projection of the first protective layer on the substrate covering the orthographic projections of the first isolation groove and the second isolation groove on the substrate,
forming a second light-emitting unit partially located in the second isolation opening, and a second protective layer and a second encapsulation unit that are located on a side of the second light-emitting unit away from the substrate, an orthographic projection of the second protective layer on the substrate covering an orthographic projection of the third isolation groove on the substrate, and
forming a third light-emitting unit partially located in the third isolation opening, and a third encapsulation unit located on a side of the third light-emitting unit away from the substrate.

22. The method according to claim 17, wherein
the at least one light-emitting unit comprises a plurality of light-emitting units, the plurality of light-emitting units comprising a first light-emitting unit, a second light-emitting unit, and a third light-emitting unit;
the at least one isolation opening comprises a plurality of isolation openings, the plurality of isolation openings comprising a first isolation opening, a second isolation opening, and a third isolation opening;
the at least one isolation groove comprises a plurality of isolation grooves, the plurality of isolation grooves comprising a first isolation groove corresponding to the first light-emitting unit, a second isolation groove corresponding to the second light-emitting unit, and a third isolation groove corresponding to the third light-emitting unit; and
the forming the at least one light-emitting unit at least partially located in the at least one isolation opening, the at least one encapsulation unit located on the side of the at least one light-emitting unit away from the substrate, and the at least one protective structure located on the side of the isolation structure away from the substrate comprises:
forming the first light-emitting unit at least partially located in the first isolation opening, and a first protective layer and a first encapsulation unit that are located on a side of the first light-emitting unit away from the substrate, an orthographic projection of the first protective layer on the substrate covering orthographic projections of the first isolation groove, the second isolation groove, and the third isolation groove on the substrate,
forming the second light-emitting unit at least partially located in the second isolation opening, and a second encapsulation unit located on a side of the second light-emitting unit away from the substrate, and
forming the third light-emitting unit at least partially located in the third isolation opening, and a third encapsulation unit located on a side of the third light-emitting unit away from the substrate.

23. The method for manufacturing the display panel according to claim 17, after the forming the at least one light-emitting unit at least partially located in the at least one isolation opening, the at least one encapsulation unit located on the side of the at least one light-emitting unit away from the substrate, and the at least one protective structure located on the side of the isolation structure away from the substrate, further comprising:
removing the at least one protective structure.
